(19) United States
(12) Patent Application Publication
(10) Pub. No.: US 2015/0105930 A1
(43) Pub. Date: Apr. 16, 2015

(54) OVERHEAD ELECTRICAL GROUNDING MESH AND MECHANICAL GRID AND OVERHEAD INFRASTRUCTURE PLATFORM STRUCTURES

(71) Applicant: LEVITON MANUFACTURING CO., INC., Melville, NY (US)

(72) Inventors: Bryan Sparrowhawk, Monroe, WA (US); Jeffrey P. Seefried, Lake Stevens, WA (US)

(21) Appl. No.: 14/573,769

(22) Filed: Dec. 17, 2014

Related U.S. Application Data
(63) Continuation-in-part of application No. 14/208,727, filed on Mar. 13, 2014.
(60) Provisional application No. 61/783,518, filed on Mar. 14, 2013.

(51) Int. Cl. H02G 7/20; G05B 15/02; G05F 1/66; H01R 25/16; G01R 11/04

(52) U.S. Cl. CPC H02G 7/20; H01R 25/162; G01R 11/04; G05F 1/66; G05B 15/02
USPC 700/297; 174/43; 361/601; 361/664

(57) ABSTRACT

An overhead infrastructure platform includes at least one horizontal support member configured to be positioned over equipment racks contained in a data center. The overhead infrastructure platform includes a module network formed by the interconnection, through a module interconnection bus, of a controller module, at least one power module and at least one I/O module. Each power module and each input/output module is physically attached to the horizontal support member proximate an equipment rack to which the module is electrically coupled.

### RELATED APPLICATIONS

The present application claims priority to, and is a continuation-in-part application of, U.S. patent application Ser. No. 14/208,727, filed 13 Mar. 2014, and entitled “OVERHEAD ELECTRICAL GROUNDING MESH AND MECHANICAL GRID STRUCTURE,” which claims the benefit of priority to U.S. Provisional Patent Application No. 61/783,518, filed 14 Mar. 2013, and entitled “OVERHEAD ELECTRICAL GROUNDING MESH AND MECHANICAL GRID STRUCTURE,” both of which applications are incorporated herein by reference in their entireties.

### TECHNICAL FIELD

The present disclosure relates generally to data centers, and, for example, to an overhead structure in a data center that provides electrical grounding functionality and mechanical structure for electrical and mechanical components, as well as sensing and monitoring components, in the data center environment.

### BACKGROUND

Data centers are buildings or portions of buildings that house electronic equipment, such as telecommunications equipment, networking equipment, computer systems like servers, and so on, along with mechanical equipment like air conditioning units and signal and power cable routing structures required for operation of the electronic equipment. Current data centers generally have a raised floor and under-floor plenum, and may have a separate plenum between the structural ceiling and a drop-down ceiling, for air circulation for heating, ventilation and air conditioning. Such plenum spaces may also be used to house signal and/or power cables and the ancillary hardware required to organize, support and manage such cabling.

In a raised floor structure, the data center includes a slab floor over which is positioned an elevated, or raised, floor on which equipment, including equipment racks and air conditioning units, may be placed. The space underneath the raised floor may be used, in addition to routing signal and power cables, to house an electrical ground grid or mesh for the data center equipment, and to provide passage for the air flow required to maintain the equipment at desired operating temperatures.

Data center design has shifted, however, away from the extensive use of the raised floor plenum for housing cabling. Instead, it is preferred to keep the raised floor plenum relatively uncluttered to ensure the unrestricted flow of air to cool data center equipment. As a result of this design shift, cabling and its associated support hardware is increasingly being displaced to overhead areas on top of, and above, the upper surfaces of equipment racks and cabinets located in the data center, and upwardly toward the ceiling region of the data center.

As a result, cables are increasingly being positioned within the data center in locations remote from the electrical ground mesh which typically remains in the raised floor plenum. This increasing physical separation of the upwardly positioned cabling and the electrical ground mesh within the raised floor plenum causes an undesirable increase in the electromagnetic susceptibility and emissions of the data center. This occurs because the physical separation of the cabling and the electrical ground mesh creates a large pick-up area of an inductive loop within the data center, as will be appreciated by those of ordinary skill in the art. It may also create an increased risk of data center equipment damage due to a nearby lightning strike or high power electrical ground fault. There is thus a need for improved data center structures that mitigate the electrical and mechanical challenges created by such data center design changes to provide reliable operation of the data center.

### SUMMARY

According to one embodiment of the present disclosure, an overhead infrastructure platform includes at least one horizontal support member configured to be positioned over equipment racks contained in a data center. The overhead infrastructure platform includes a modularized network formed by the interconnection, through a module interconnection bus, of a controller module, at least one power module and at least one I/O module. Each power module and each input/output module is physically attached to the horizontal support member proximate an equipment rack to which the module is electrically coupled.

### BRIEF DESCRIPTION OF THE DRAWINGS

FIG. 1 is a perspective view of a data center including an overhead electrical grounding mesh and mechanical grid structure.

FIG. 2A is a cross-sectional view of the data center of FIG. 1.

FIG. 2B is a cross-sectional view of a data center including a slab floor according to another embodiment of the present disclosure.

FIG. 3 is a perspective view of the data center of FIGS. 1 and 2 showing several examples of equipment that may be attached to and supported by the overhead electrical grounding mesh and mechanical grid structure.

FIG. 4 is a perspective view of a data center such as the data center of FIGS. 1 and 2 showing a cutaway view of the raised floor.

FIG. 5 is a perspective view of a data center including an overhead cable rack for routing signal cables.

FIG. 6 is a perspective view of one of the cross-beam portions in the structure of FIG. 1.

FIG. 7 is another perspective view of one of the cross-beam portions of FIG. 1 illustrating foldable grid beams to allow for access into the space above the structure.

FIG. 8 is another perspective view of one of the cross-beam portions of FIG. 1 showing the foldable grid beams of FIG. 7.

FIG. 9 is a perspective view of one of the cross-beam portions of FIG. 1.

FIG. 10 is a cross-sectional view of the cross-beam portion of FIG. 9.

FIG. 11 is a bottom view of the cross-beam portion of FIG. 9.

FIG. 12 is a perspective view illustrating a cross-beam portion similar to that of FIG. 9 except with a compression bale on top of the cross-beam portion.

FIG. 13 is a perspective view of one of the cross-beam portions of FIG. 1 where one of the cross beams includes an indexing cutout to provide easy equidistant spacing of cross beams during assembly of the grid structure.

FIG. 14 is a perspective view of one embodiment of one of the grid beams of FIG. 1.

FIG. 15A is a perspective view of an overhead infrastructure platform (OIP) having attached power modules positioned over equipment racks contained in a data center according to another embodiment of the present disclosure.

FIG. 15B is a perspective view of the OIP of FIG. 15A showing input/output (I/O) modules and a power supply module that are also attached to the OIP.

FIG. 16 is a cross-sectional view of a portion of one embodiment of the OIP of FIGS. 15A and 15B illustrating both the power and I/O modules attached to the OIP and illustrating the coupling of each of these modules to a corresponding equipment rack.

FIG. 17 is a functional block diagram of one of the power modules of FIG. 15A according to one embodiment of the present disclosure.

FIG. 18 is a functional block diagram of one of the I/O modules of FIGS. 15B and 16 according to one embodiment of the present disclosure.

FIG. 19 is a functional block diagram of the controller module of FIGS. 15A and 15B according to one embodiment of the present disclosure.

FIG. 20 is a functional block diagram illustrating direct current (DC) power and communications interconnections between the power modules, I/O modules, and controller module of FIGS. 15A, 15B, and 16 according to one embodiment of the present disclosure.

FIG. 21 is a cross-sectional view of a portion of an OIP including multiple levels of horizontal support members positioned over equipment racks according to another embodiment of the present disclosure.

FIG. 22 is a cross-sectional view of a portion of an OIP including an L-shaped mounting bracket for mounting the power and I/O modules according to a further embodiment of the present disclosure.

FIG. 23 is a cross-sectional view of a portion of an OIP where the horizontal support members include an end portion that extends beyond an end vertical support member and where the power and I/O modules are mounted to this end portion according to still another embodiment of the present disclosure.

FIG. 24 is a perspective view of an external networked power distribution unit (PDU) that may be mounted to the mechanical grid structure of FIG. 1 or the overhead infrastructure platform (OIP) of FIG. 15A, or any other suitable “fixed” location within a data center, according to another embodiment of the present disclosure.

FIG. 25 is a functional block diagram illustrating one embodiment of the external networked PDU of FIG. 24.

FIG. 26 illustrates various cross-sectional shapes of a bead at upper and lower portions of a grid-beam, according to various embodiments of the present disclosure.

### DETAILED DESCRIPTION

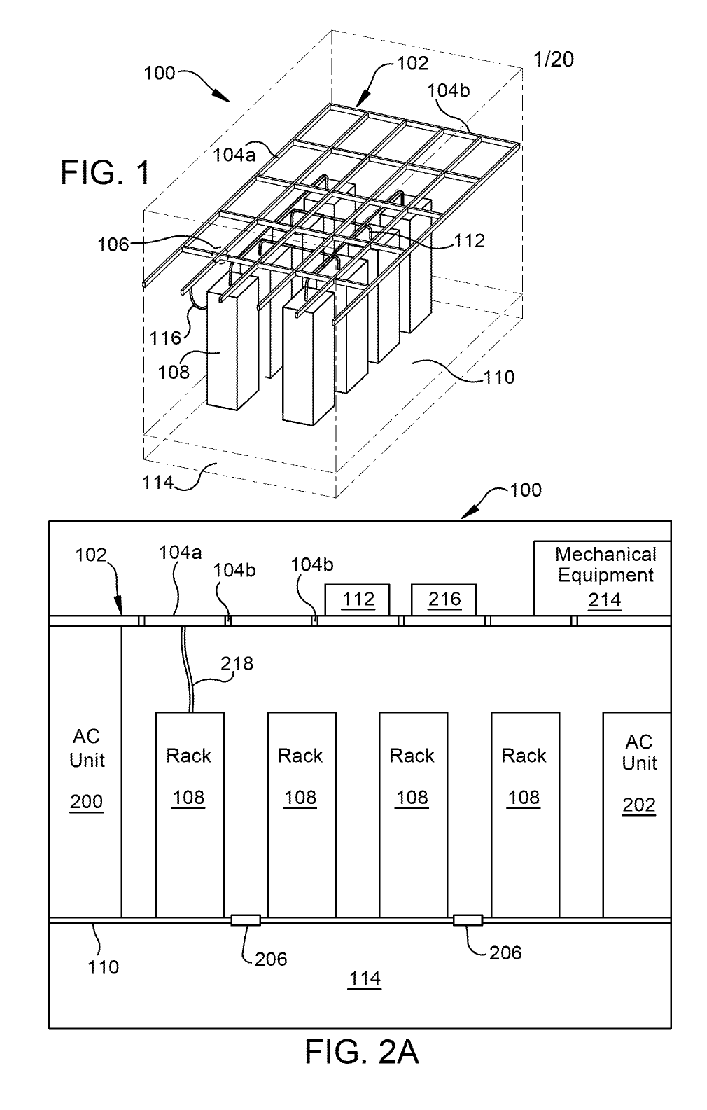

FIG. 1 is a perspective view of a data center 100 including an overhead electrical grounding mesh and mechanical grid structure 102 according to one embodiment. The grid structure 102 includes a number of orthogonally arranged grid beams 104a and 104b that interconnect at cross-beam portions 106 and are formed from a material, and of a size suitable, to provide both required electrical grounding and structural support for the mounting of electronic and mechanical equipment (not shown) in the data center, as will be described in more detail below. In this way the grid structure 102 functions as both the electrical ground mesh for the data center 100 while also being a mechanical structure to which signal cables and mechanical equipment, such as air conditioning units, control modules and environmental monitoring equipment, and the like, can be mounted. The disclosed grid structure 102 may even be of sufficient strength to support pipes and ducting, such as may be associated with an HVAC system, along with ladders, catwalks and the like to permit humans to climb, crawl and/or walk upon for enhanced access to the electronic and mechanical equipment mounted thereon.

In the following description, certain details are set forth in conjunction with the described embodiments to provide a sufficient understanding of the subject disclosure. One of ordinary skill in the art will appreciate, however, that the embodiments of this disclosure may be practiced without these particular details. Furthermore, one of ordinary skill in the art will appreciate that the example embodiments described below do not limit the scope of the present disclosure, and will also understand that various modifications, equivalents, and combinations of the disclosed embodiments, and components thereof, are within the scope of the present disclosure. Embodiments including fewer than all the components of any of the respective described embodiments may also be within the scope of the present disclosure although not expressly described in detail below. Finally, the operation of well-known components, structures, and/or processes has not been shown or described in detail below to avoid unnecessarily obscuring the present disclosure.

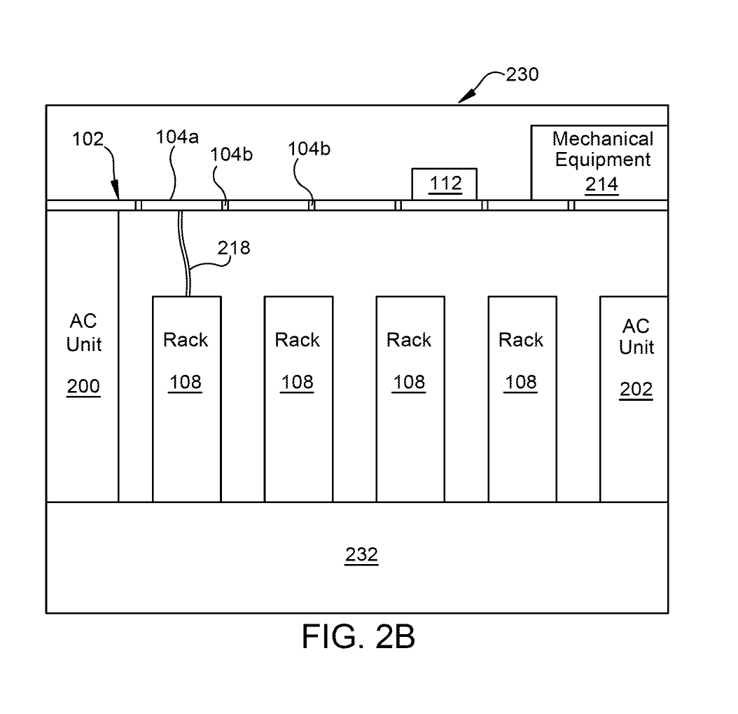

As seen in FIG. 1, the data center 100 includes a number of equipment racks 108 that house electronic equipment (not shown), such as computer servers. The racks 108 rest on a raised floor 110 and the electronic equipment in the racks is connected to signal and power cables 112. The grid structure 102 is a rigid structure and supports the cables 112 to facilitate the routing of the cables as required. A space or raised-floor plenum 114 under the raised floor 110 (and/or a plenum in a drop down ceiling (not shown)) functions to channel the flow of air for cooling the equipment racks, as will be described in more detail below with reference to FIG. 2A. The rigid grid structure 102 is formed from a suitable size and material, such as copper-coated aluminum, to provide the required rigid support structure and electrical ground mesh for the equipment in the racks 108. For one of the equipment racks 108, a ground cable 116 is shown connected to the grid structure to provide the required ground connection for the corresponding rack, and such a cable or cables would typically be present for each equipment rack although not expressly shown in FIG. 1.

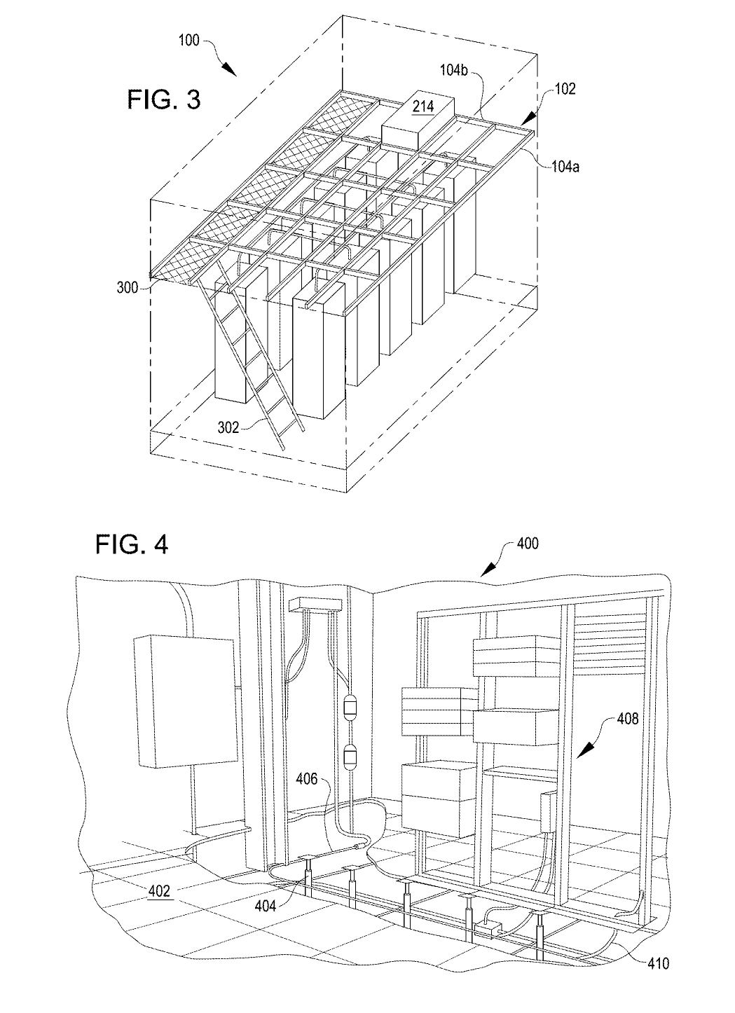

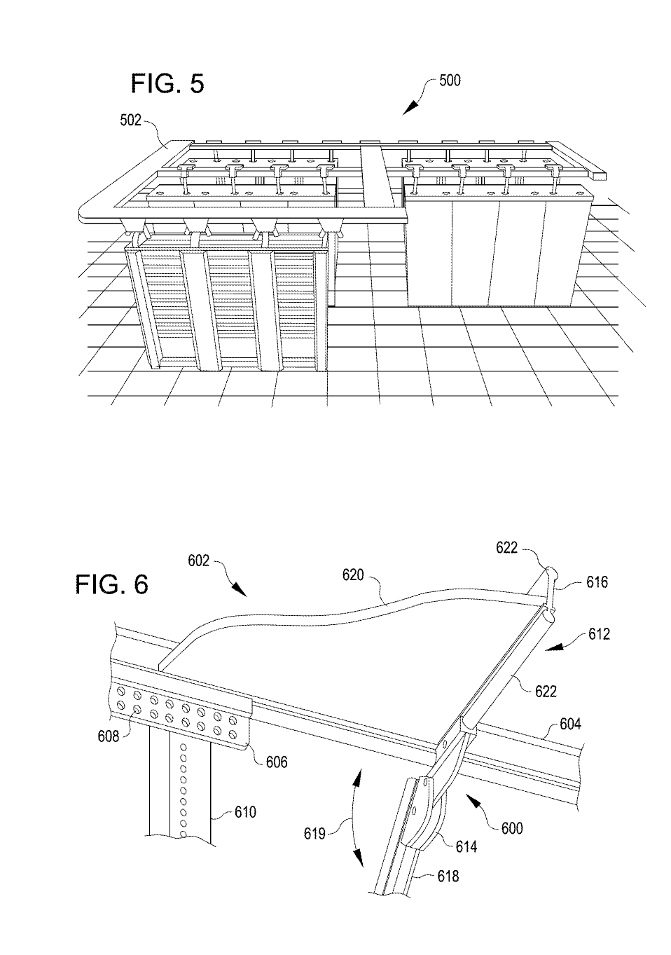

Before describing the grid structure 102 in more detail, some of the additional physical features of the data center 100 will be discussed with reference to FIGS. 2 and 3 and contrasted to conventional data centers with reference to FIGS. 4 and 5 in order to better understand additional aspects of the grid structure subsequently described with reference to FIGS. 6-14. Common components between FIG. 1 and FIGS. 2-5 have been given the same reference numbers as assigned to these components in FIG. 1.

FIG. 2A is a cross-sectional view of the data center 100 showing the equipment racks 108 as well as air conditioning (AC) units 200, 202 (not shown in FIG. 1) resting on the raised floor 110 that function to maintain the data center, and thereby the electronics in the equipment racks, at a desired operating temperature. The AC units 200, 202 provide cool airflow in the raised-floor plenum 114 under the raised floor 110 and this cool air has sufficient pressure to enter the area above the raised floor through vented tiles 206 in the raised floor. The grid structure 102 above the equipment racks 108 is shown with the AC unit 200 attached at its top end to the grid structure 102. The same could be true for AC unit 202 as well as some or all of the equipment racks 108.

As previously described and depicted in FIG. 2A, the grid structure 102 is sufficiently rigid such that it can provide structural support for components in the data center 100. In addition to the AC unit 200 and other mechanical equipment being attached to the grid structure 102 from below, mechanical equipment, structural devices, and electronic components may also be attached to the grid structure from above. For example, mechanical equipment 214 is shown attached to the grid structure 102 from above and is thus contained in an area 216 above the grid structure. This mechanical equipment 214 may be any of a variety of different types of equipment, such as additional AC units, control modules, power modules, monitoring modules, structural devices like a catwalk attached to the grid structure to allow maintenance personnel to walk or crawl on the catwalk and service equipment located above the grid structure 102, and so on. Electronic components such as signal and power cables may also be physically attached to the grid structure 102, either from above or below the grid structure. A box labeled 112 on the grid structure 102 represents signal and power cables 112 that are physically attached to and supported by the grid structure. The grid structure 102 in this way functions as structural support to allow for the routing of cables between the equipment racks 108 and otherwise as necessary within the data center 100.

As previously described and further depicted in FIG. 2A, the grid structure 102 is constructed from a suitable electrically conductive material so as to function as the grounding mesh for the data center 100. Accordingly, each of the equipment racks 108 would be electrically connected to the grid structure 102 through a corresponding grounding cable, with such a grounding cable 218 being illustrated only for the equipment rack on the far left of FIG. 2A. In this way, the grid structure 102 provides both structural support and the electrical grounding mesh for the data center.

Positioning the grid structure 102 above the equipment and racks 108 in a data center positions the grounding mesh proximate the signal cables and is advantageous for reducing unwanted electromagnetic interference within the data center. For example, as previously mentioned, signal cables and power cables are increasingly being positioned above the equipment racks 108 instead of in the space 114 below the raised floor 110 to ensure there is adequate space for required airflow in the space 114. Leaving the ground mesh under the raised floor 110 while positioning the signal cables above the equipment racks 108 undesirably increases the electromagnetic susceptibility of the electronic equipment contained in the equipment racks due to the enlarged pick-up area of an inductive loop created by the greater distance between such signal cables and the under-the-floor ground mesh. The grid structure 102 reduces such electromagnetic susceptibility through its positioning proximate the signal cables coupled to the grid structure. The grid beams 104a and 104b need not be orthogonally arranged, and in other embodiments the grid structure 102 includes grid beams 104a and 104b arranged differently. For example, referring back to FIG. 1, the grid beams 104a may be arranged as shown in the figure while grid beams 104b are then arranged at an angle other than ninety degrees (i.e., are not orthogonal) relative to the grid beams 104a. Other embodiments could likewise include orthogonally arranged grid beams 104 and grid beams not arranged orthogonally.

FIG. 2B is a cross-sectional view of a data center 230 including a slab floor 232 instead of the raised floor 110 of the embodiment of FIG. 2A. The slab floor 232 would typically be formed from a reinforced concrete structure, but may be formed of any suitable structure and material. The other components 102, 104a, 104b, 108, 112, 200, 202, 214, and 218 are the same as the corresponding components in FIG. 2A and thus will not again be described in detail. Because the overhead electrical grounding mesh and mechanical grid structure 102, which includes grid beams 104a and 104b, provides the ground grid for the electronic components in the racks 108 and other electronic components in the data center 230, the raised floor 110 is no longer need for housing the ground grid. In a conventional data center containing a raised floor, the ground grid would typically be contained within the plenum of the raised floor.

FIG. 3 is a perspective view of the data center 100 of FIGS. 1 and 2 showing several examples of equipment that may be attached to and supported by the overhead electrical grounding mesh and mechanical grid structure 102. In the example of FIG. 3, the grid structure 102 includes a catwalk 300 constructed on the grid beams 104a and 104b as shown. A ladder 302 is shown supported by the grid structure 102 and may be utilized by maintenance personnel (not shown) to climb up onto the catwalk 300 to gain access to mechanical, monitoring, power and electrical equipment from above the grid structure. For example, a person could climb up the ladder 302 onto the catwalk 300 and then walk down the catwalk to gain access to the mechanical equipment 214 previously discussed with reference to FIG. 2A, or to route or repair signal and power cables 112, or any other mechanical, monitoring, power or electronic equipment that may only be accessed or may be more easily accessed from above the grid structure 102.

FIGS. 4 and 5 are perspective views of conventional data centers 400 and 500 that will now be described to better illustrate the different mechanical and electrical characteristics of the data center 100 of FIGS. 1-3. FIG. 4 shows a cutaway view of a conventional raised floor 402 including vertical floor supports 404 that support the raised floor. As seen in the cutaway, a grounding mesh 406 is also routed under the raised floor 402 with equipment racks being electrically grounded to the mesh 406, as illustrated via cables 410. Although not shown in FIG. 4, in the data center 400 the signal and power cables may be routed overhead the equipment racks 408 as shown in FIG. 5 which illustrates a data center 500 that includes a conventional overhead cable pathway structure 502 that could be utilized in routing the required cables overhead in the data center 400 of FIG. 4. Note that with this approach, the signal and power cables may be routed overhead and above the equipment racks 408 in both data centers 400, 500 while the grounding mesh 406 may be positioned under the equipment racks 408 in the area under the raised floor 402 as shown in FIG. 4 but which may also be present in data center 500 as shown in FIG. 5. As previously mentioned with regard to the embodiments of FIGS. 1-3, such a separation between the signal and power cables and the grounding mesh in conventional data centers 400, 500 shown in FIGS. 4 and 5 undesirably increases the electromagnetic interference susceptibility of the data center. Furthermore, note that the overhead cable path structure 502 of conventional data center 500 shown in FIG. 5 is simply a structure attached to the equipment racks to facilitate the overhead routing of cables and does not function as the grounding mesh or provide structural support for mechanical equipment.

FIG. 6 is a perspective view of one cross-beam portion 600 in a grid structure 602 corresponding to one embodiment the grid structure 102 of FIG. 1. The cross-beam portion 600 is accordingly one embodiment of the cross-beam portions 106 previously described with reference to FIG. 1. The grid structure 602 includes longitudinal grid-beams 604 that extend over a length of the data center 100 and are attached at their ends to the walls of the data center (not shown in FIGS. 1 and 6). As previously described, these longitudinal grid-beams 604 are formed from a suitable material and size so as to be both electrically conductive to provide the grounding mesh function of the grid structure 602 as well as being sufficiently rigid to provide structural support for mechanical components located in the data center 100.

In the embodiment of FIG. 6, the longitudinal grid-beam 604 is formed such that mounting plates 606 can be attached to the grid-beam to allow mechanical, electrical, monitoring or power equipment to thereby be attached to and supported by the grid-beam. As seen in FIG. 6, the mounting plate 606 includes a plurality of holes 608 to allow for bolts or other suitable attachment means to be inserted through the holes to secure desired mechanical equipment (not shown) to the mounting plate. For example, in FIG. 6 a vertical rack member 610 of one of the equipment racks 108 (FIG. 1) is shown and would be attached to the mounting plate 606 through suitable bolts or other attachment means inserted through the holes 608, although no such bolts or attachment means are expressly illustrated in FIG. 6. In this way, one or more of the equipment racks 108 can be attached to the grid structure 602 to provide improved seismic characteristics of the data center 100, for example.

The grid structure 602 further includes collapsible transverse grid-beams 612 that are attached to the longitudinal grid-beam 604 at corresponding cross-beam portions 600 through an attachment and hinge structure 614. The collapsible transverse grid-beam 612 includes a first transverse grid-beam section 616 having one end attached to the hinge structure 614 and a second transverse grid-beam section 618 having one end attached to the hinge structure as shown in FIG. 6. Hinge structure 614 is also formed from a suitably rigid and electrically conductive material. The hinge structure 614 is configured so that the contact between the hinge structure and the longitudinal grid-beam 604 is sufficient to ensure proper electrical connection of the longitudinal grid-beam to the transverse grid-beam sections 616, 618. All longitudinal grid-beams 604 and transverse grid-beam sections 616, 618 must be electrically coupled via the hinge structures 614 for the grid structure 602 to provide the grounding mesh functionality for all electronic equipment connected to the grid structure (i.e., connected to the grid-beams or grid-beam sections.) Thus, the hinge structures 614 contact the longitudinal grid-beams 604 with sufficient pressure to provide this required electrical interconnection.

In operation, one or both of the grid-beam sections 616, 618 can be folded downward from a horizontal position, which is the position of the transverse grid-beam section 616 in FIG. 6, to allow access to equipment (not shown in FIG. 6) contained above the grid structure 602. The arrow 619 in FIG. 6 shows that in the embodiment of FIG. 6, the transverse grid-beam section 618 may be moved from the horizontal or raised position (e.g., same position as that of transverse grid-beam section 616) to a lowered position as shown in FIG. 6.

Grid structure 602 is further configured to support ceiling tiles 620, much as does a conventional suspended or “drop ceiling” prevalent in commercial office buildings. This enables equipment above the grid structure 602 to be hidden from view when the tiles 620 are in place, and can also provide an area above the grid structure 602 for additional airflow control as does a conventional drop ceiling.

In the embodiment depicted in FIG. 6, the transverse grid-beam sections 616 and 618 each include a rounded portion or bead 622 on an upper and lower portion of the sections. The bead 622 is how the hinge structure 614 is attached to the transverse grid-beam sections 616 and 618, as seen most clearly for the transverse grid-beam section 616 in the FIG. 6. The hinge structure 614 includes pieces adapted to go around the bead 622 and suitable attachment means, such as screws, through which the hinge structure is secured around the bead 622 and thereby attached to the transverse grid-beam sections 616 and 618. It is to be appreciated that in other embodiments, the bead 622 can be a shaped differently than depicted in FIG. 6. For example, the bead 622 can be a triangle portion, a flange portion (e.g., a horizontal flat flange portion, an I-beam flange portion, etc.), another shaped portion, etc. In certain embodiments, the bead 622 can also be textured (e.g., a textured rounded portion, etc.).

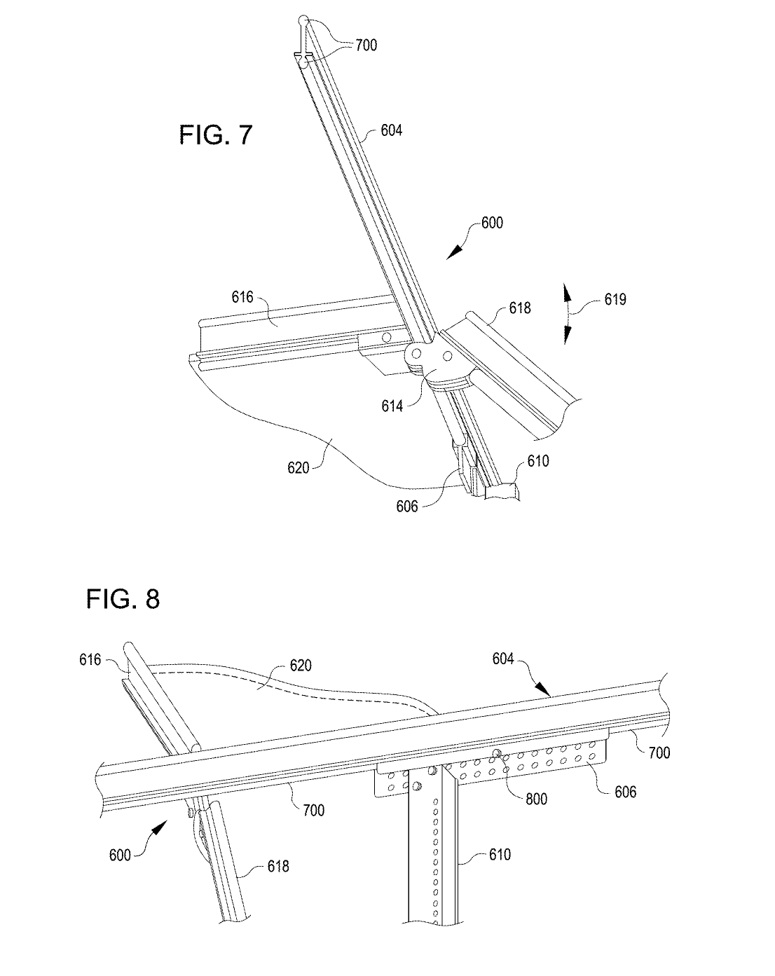

FIG. 7 is another perspective view of the grid-beam portion 600 of FIG. 6 further illustrating the foldable functionality of the transverse grid-beam section 618. In addition, FIG. 7 illustrates a bit more detail about the specific structure of the longitudinal grid-beam 604 and the attachment of the mounting plate 606 to the longitudinal grid-beam 604. The longitudinal grid-beam 604 also includes a bead 700 at the upper and lower portions of grid-beam 604 to allow components to be attached, such as the mounting plate 606 as seen in FIG. 7. The mounting plate 606 is secured around the lower bead 700 of the longitudinal grid-beam 604 in the same way as described for the hinge structure 614 being attached to the sections 616 and 618 with reference to FIG. 6. One or more components other than the mounting plate 606 can additionally or alternatively be secured to (e.g., attached to, hung from, etc.) a lower bead 700 of the longitudinal cross-beam 604, such as but not limited to, one or more modules (e.g., power modules, controller modules, I/O modules, modules associated with racks, servers and/or switches, modules associated with a fixed infrastructure of a data center, enclosures, units, etc.), rack rails (e.g., free standing open frame rack rails), panels (e.g., patch panels), etc. Additionally or alternatively, one or more components can be secured to (e.g., attached to, etc.) an upper bead 700 of the longitudinal cross-beam 604, such as but not limited to, a grid structure and/or components associated with the grid structure (e.g., ducts, catwalks, trays, etc. attached to an upper surface of the grid structure, etc.) In the embodiment depicted in FIG. 7, the bead 700 comprises a rounded shape. However, it is to be appreciated that the bead 700 can comprise a different shape, such as but not limited to, a triangular shape, a flanged shape, another shape, etc. Moreover, in certain embodiments, the bead 700 can comprise a texture (e.g., a textured surface) to facilitate improved attachment of components to attach to the bead 700.

FIG. 8 is another perspective view of the cross-beam portion 600 of FIG. 6 showing in more detail the attachment of the vertical rack member 610 to the mounting plate 606. As seen in the FIG. 8, a screw 800 secures the mounting plate 606 around the lower bead 700 of the longitudinal cross-beam 604 in this embodiment.

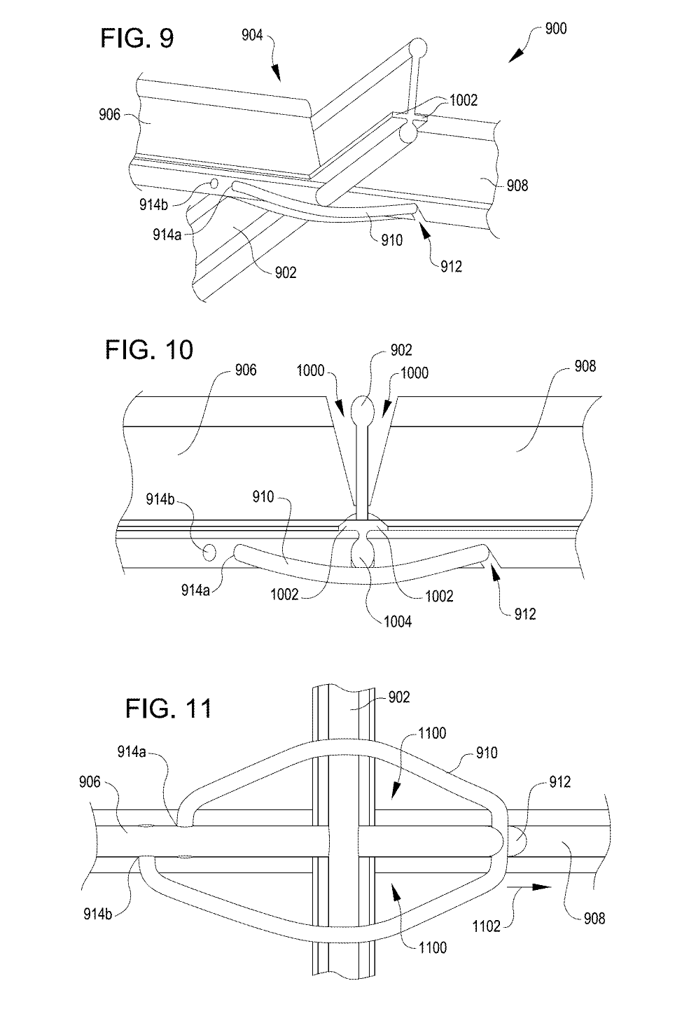

FIG. 9 is a perspective view of a cross-beam portion 900 corresponding to another embodiment of one of the cross-beam portions 106 of FIG. 1. In the embodiment of FIG. 9, the cross-beam portion 900 is formed at the intersection of a longitudinal grid-beam 902 and a transverse grid-beam 904 including transverse grid-beam sections 906 and 908. The transverse cross-beam sections 906 and 908 are held in place on the respective sides of the longitudinal grid-beam 902 through a spring 910 made of a suitable steel or other suitable elastic material. The spring 910 is secured at one end in a groove 912 formed in the lower end of the transverse grid-beam section 908. The spring 910 is secured at the other end via suitable holes 914a and 914b formed in the lower portion of the transverse grid-beam section 906 (see also FIGS. 10, 11 and 12). The hole 914a is formed in the lower front portion of the transverse grid-beam section 906 seen in FIG. 9 while the hole 914b is formed in the lower back portion of transverse grid-beam section 906, or the holes 914a, 914b can extend entirely through the lower portion of the transverse grid-beam section 906 from the front to the back, as will be described in more detail below with reference to FIG. 11.

FIG. 10 is a cross-sectional view of the cross-beam portion 900 of FIG. 9 showing the cross-sectional shape of the longitudinal grid-beam 902 along with the shape of end portions 1000 of the transverse grid-beam sections 906 and 908 in this embodiment. The longitudinal grid-beam 902 includes horizontal projections 1002 (see also FIG. 9) extending from sides of grid-beam 902 near a lower bead 1004 of the grid-beam. The horizontal projections 1002 are configured to engage the end portions 1000 of the transverse grid-beam sections 906 and 908 as illustrated. FIG. 10 illustrates the cross-beam portion 900 secured in place within the grid structure 102 (FIG. 1). One or more components can be attached to (e.g., hung from) the lower bead 1004. For example, one or more modules (e.g., power modules, controller modules, I/O modules, enclosures, units, etc.) associated with servers, switches and/or racks of a data center floor (e.g., a raised floor, a slab floor, etc.), one or more modules (e.g., power related enclosures, etc.) associated with data center infrastructure (e.g. fixed infrastructure of a data center), frame rack rails (e.g., free standing open frame rack rails), panels (e.g., patch panels), mounting plates and/or other components can be attached to the lower bead 1004. In the embodiment depicted in FIG. 10, the lower bead 1004 comprises a cylindrical cross-sectional shape. However, it is to be appreciated that the lower bead 1004 can comprise a different cross-sectional shape, such as but not limited to, a triangular cross-sectional shape, a flanged cross-sectional shape, another type of cross-sectional shape associated with a “negative draft” so as to enhance an ability of components to attach to the lower bead 1004 with minimal clamping force, etc. In one embodiment, the lower bead 1004 can be associated with a smooth surface. In another embodiment, the lower bead 1004 can be associated with a textured surface.

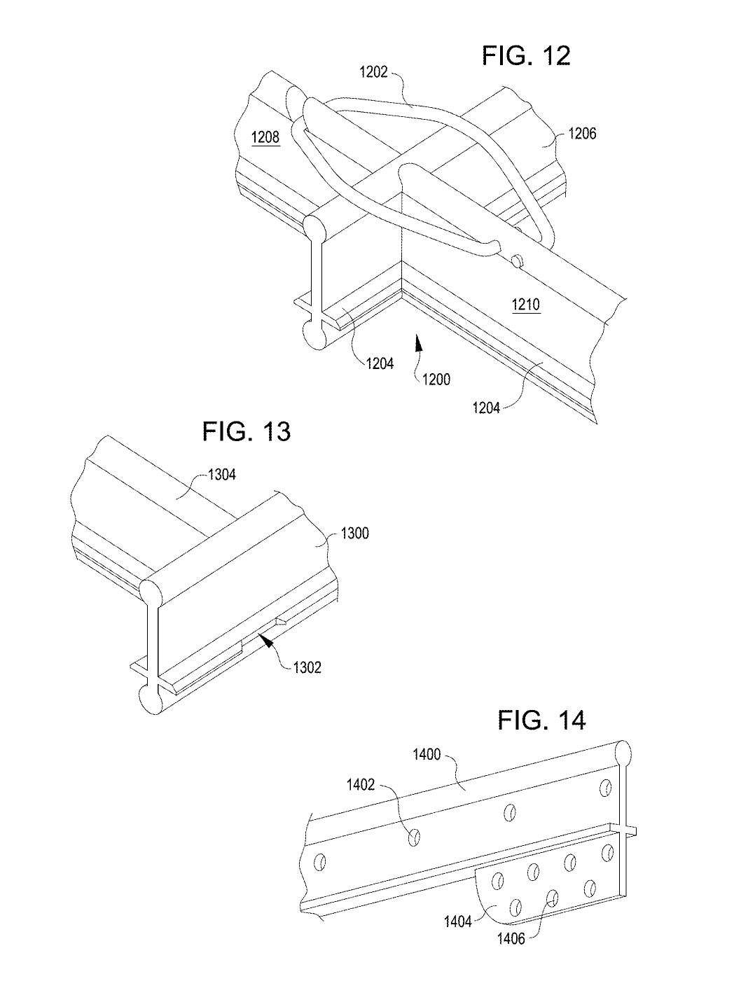

FIG. 11 is a bottom view of the cross-beam portion 900 of FIGS. 9 and 10. To gain access to the area above the grid structure 102 (e.g., to temporarily remove the cross-beam portion 900) a person would squeeze the spring 910 inward in the direction indicated by arrows 1100 in FIG. 11. Since the ends of the spring 910 are secured in the holes 914a and 914b, the right end of the spring 910 in the groove 912 will shift rightward in the groove as indicated by the arrow 1102 until the spring can be removed from the groove at this right end and folded downward. At this point, the transverse grid-beam sections 906 and 908 can be removed by moving the sections in the direction indicated by either arrow 1100 until the section can be removed from engagement with the horizontal projections 1002 of the longitudinal cross-beam 902 (see FIG. 10). FIG. 12 is a perspective view illustrating a cross-beam portion 1200 similar to the cross-beam portion 900 of FIG. 9 except in this embodiment a spring 1202 is positioned on top of the cross-beam portion instead of on the bottom of the cross-beam portion as in FIG. 9. In this way, the spring 1202 may be hidden from view when the cross-beam portion 1200 of the grid structure 102 (FIG. 1) containing the cross-beam portion is secured in place. Note that in this embodiment the ceiling tiles 620 (FIG. 6) or other fixtures, including but not limited to lighting fixtures, would need to be flexible so that each tile can be flexed and inserted under the spring 1202 to rest on a ledges 1204 contained on longitudinal cross-beam 1206 and transverse cross-beam sections 1208 and 1210.

FIG. 13 is a perspective view of another embodiment of the cross-beam portion 106 FIG. 1 in which a longitudinal cross-beam 1300 includes an indexing feature 1302 in the form of a cutout in this embodiment. The indexing feature 1302 allows transverse cross-beam sections 1304 to be positioned at precise locations along a length of the longitudinal cross-beam 1300. Thus, an end of a transverse cross-beam section 1304 would fit into the indexing feature 1302 to thereby position the section at this precise location along the length of the longitudinal cross-beam 1300.

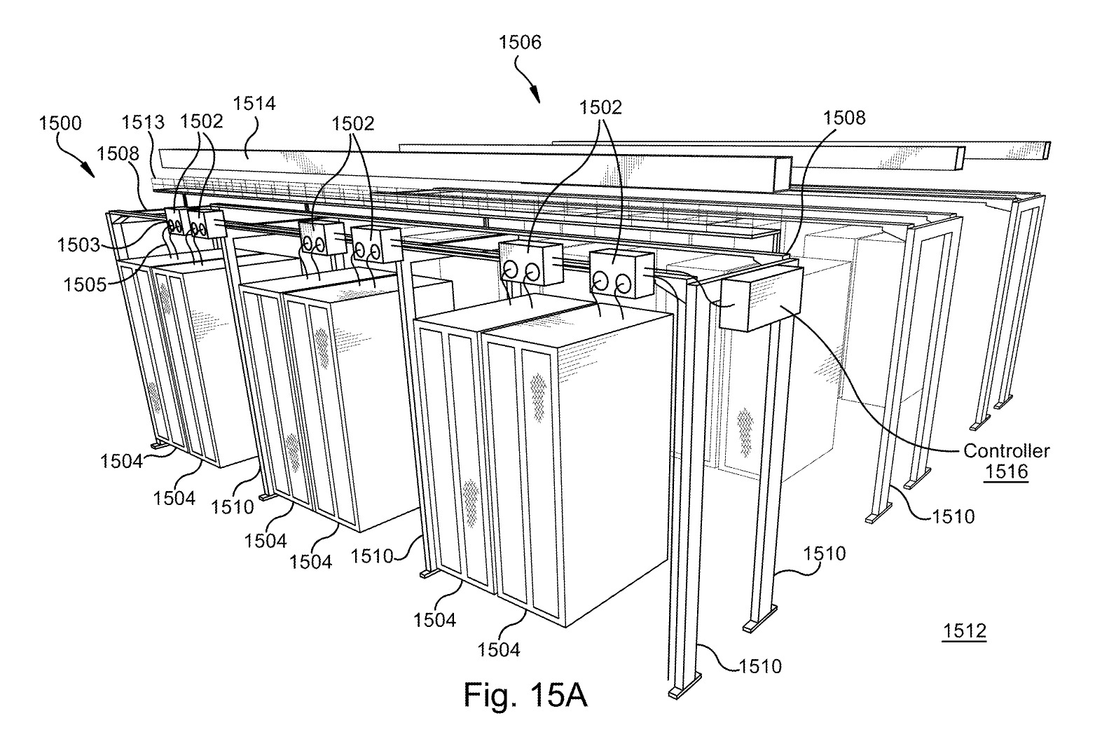

FIG. 14 is a perspective view of a portion of a grid beam 1400 corresponding to one embodiment of one of the grid beams 104a or 104b of FIG. 1 as well as the grid beams discussed with reference to FIGS. 6, 9, 12, 13. In this embodiment, the grid beam 1400 includes holes extending along a length of the grid beams to allow for easy mounting of equipment to the grid beam. In addition, the grid beam 1400 includes an integral mounting plate 1404 including a plurality of holes 1406 once again for attaching equipment to the mounting plate and thereby securing the equipment to the grid structure including the grid beam 1400.

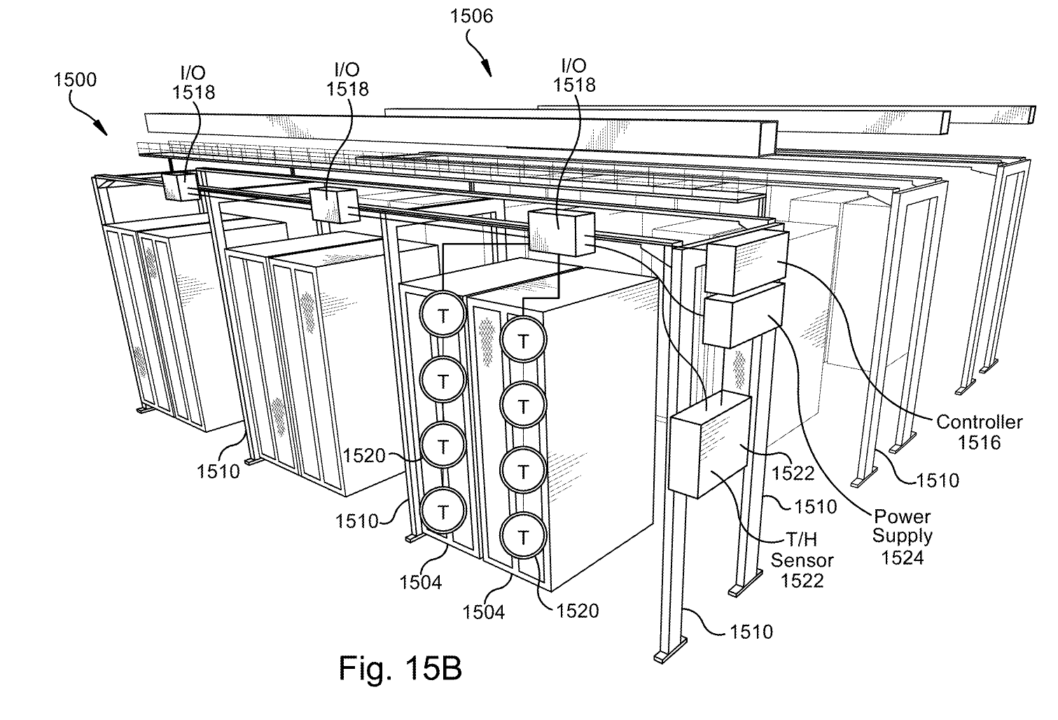

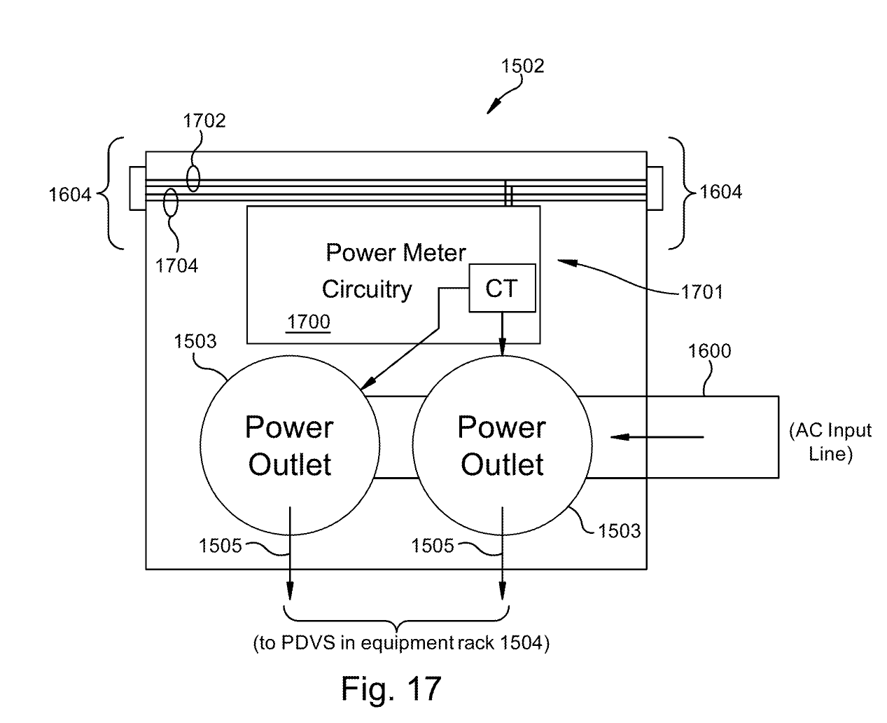

FIG. 15A is a perspective view of an overhead infrastructure platform (OIP) 1500 having attached power modules 1502 positioned over equipment racks 1504 contained in a data center 1506 according to another embodiment of the present disclosure. Each of the power modules 1502 is attached to the OIP 1500 proximate the equipment rack 1504 to which that power module is connected. More specifically, in the embodiment of FIG. 15 the OIP 1500 includes a number of horizontal members 1508 and each power module 1502 is attached to one or more horizontal support member to position the power module approximately over the corresponding equipment rack 1504. In an example, a power module 1502 and/or another module (e.g., I/O module, controller module, etc.) can be attached to a horizontal member 1508 via a bead (e.g., a lower bead) of the horizontal member 1508. Each power module 1502 includes two power ports 1503, each port being adapted to receive a corresponding AC coupling line 1505 that couples the power module to a respective power distribution unit (PDU) (not shown) in the corresponding equipment rack 1504. One embodiment of the power modules 1502 is described in more detail below with reference to FIG. 17.

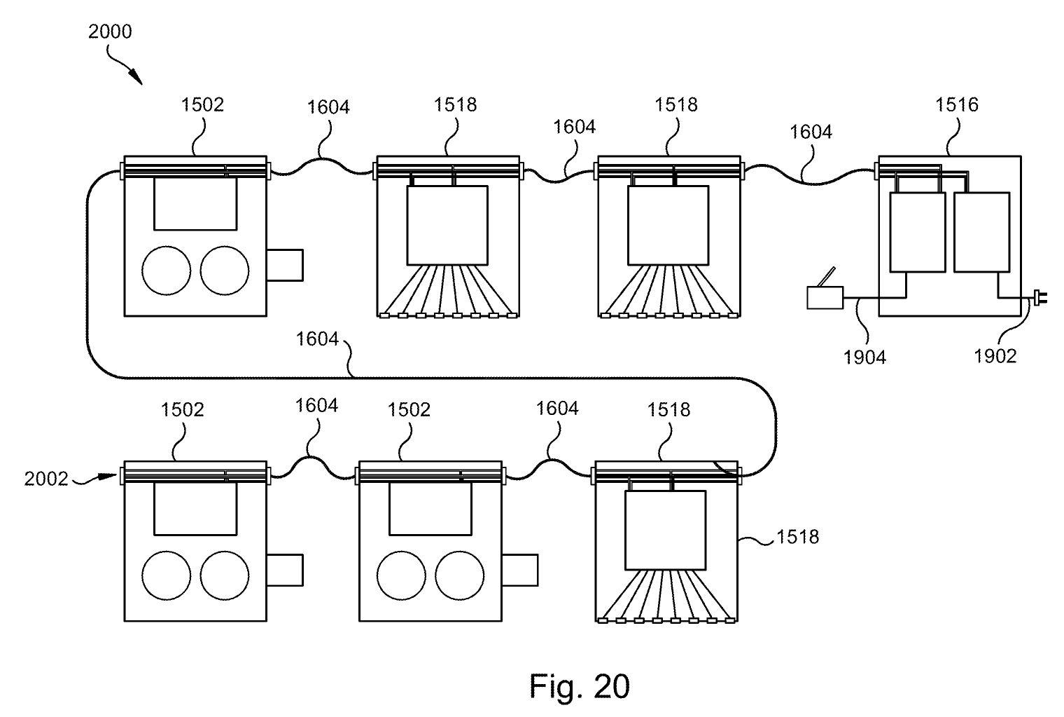

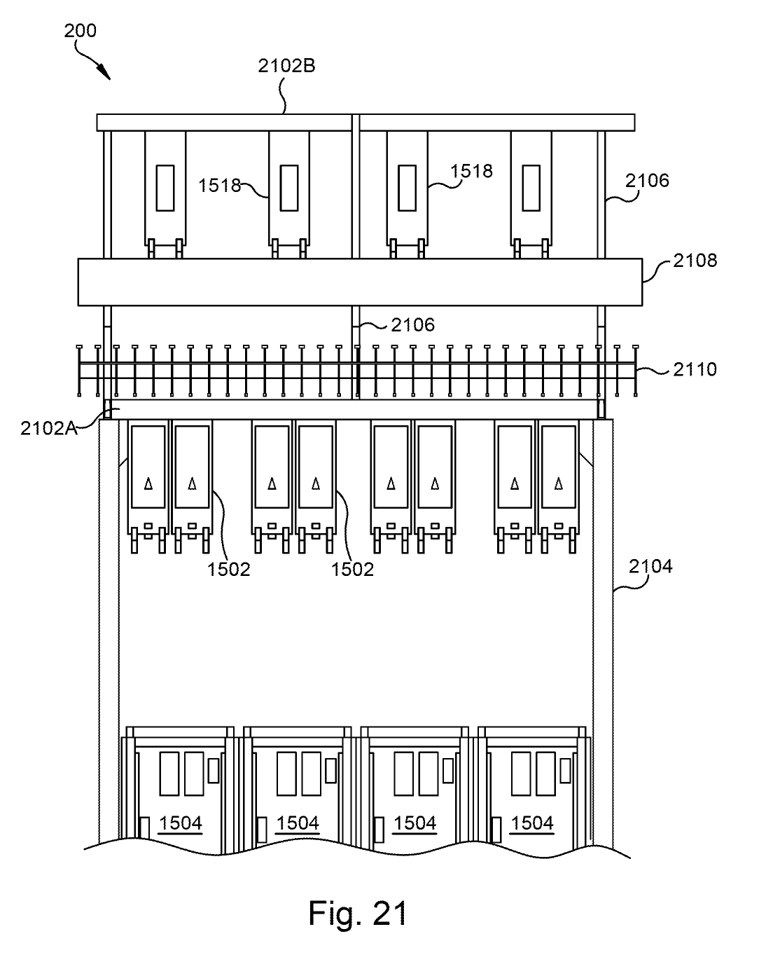

The OIP 1500 further includes a number of vertical support members 1510, each vertical support member having a lower end connected to a floor 1512 of the data center 1506 and an upper end coupled to support the horizontal support members 1508 over the equipment racks 1504. The OIP 1500 may also include other components, such as cable routing structures 1513 and 1514, mounted to the horizontal support members 1508, as will be described in more detail below. These cable routing structures 1513 and 1514 may be any of a variety of overhead infrastructure elements typically contained within a data center, such as cable pathways including ladder trays, basket trays, structures for routing power cables, and so on, as will be appreciated by those skilled in the art. A controller 1516 is also mounted to the OIP 1500 and is coupled to the power modules 1502 through a module interconnection bus including power and communications links, as will also be explained in more detail below with reference to FIGS. 20 and 21.

FIG. 15B is another perspective view of the OIP 1500 of FIG. 15A showing a number of input/output (I/O) modules 1518 that are also attached to one or more of the horizontal support members 1508 (See FIG. 15A) to position the I/O module approximately over the corresponding equipment rack 1504 to which the module is connected. More specifically, each I/O module 1518 is coupled to a number of sensors 1520 positioned within, or proximate to, the corresponding equipment rack 1504, or within the data center 1506 itself, including in, on or proximate to OIP 1500 and/or grid structures 102, 602, that function to sense operational parameters, such as temperature, humidity, current, air quality, air flow, leak, pressure and power, at different locations in the equipment rack or in the data center. The sensors 1520 in the example of FIG. 15B are temperature sensors, denoted with a “T,” and humidity sensors, designated with a “H.” The sensors 1520 may include sensors that sense other parameters as well, such as security sensors like door contact sensors indicating whether the door of the corresponding equipment rack 1504 is opened or closed. Such security-type sensors 1520 may also include motion sensors to sense the presence of personnel in the data center 1506. The sensors 1520 may be located within, or proximate to, the equipment racks 1504 or within the data center 1506 itself, and in this way may sense rack specific parameters or parameters that provide information for the entire data center or a portion of the data center larger than within a specific rack. One example of such a sensor, namely a temperature/humidity (T/H) sensor 1522, is shown in FIG. 15B.

A single I/O module 1518 is coupled to sensors 1520 contained in two equipment racks 1504 in the embodiment of FIG. 15B. The additional sensor 1522 is also attached to the OIP 1500, or grid structure 102, 602, and designated as a “T/H” sensor in the figure to indicate the sensor may be a temperature or humidity sensor. This sensor 1522 senses the temperature and/or humidity inside the data center 1506 itself, or a portion of the data center, instead of the temperature and/or humidity within an individual equipment rack 1504. The I/O modules 1518 and sensor 1522 are coupled to the controller module 1516 through suitable analog or digital connections, and the controller module utilizes these sensors in sensing operational data for each of the equipment racks 1504 and for the data center 1506, as will be explained in more detail below. A power supply module 1524, which may be a separate module or may be part of the controller module 1516, is also coupled to the I/O modules 1518 to supply low voltage (less than 100V AC or DC) power to the modules, as will also be explained in more detail below.

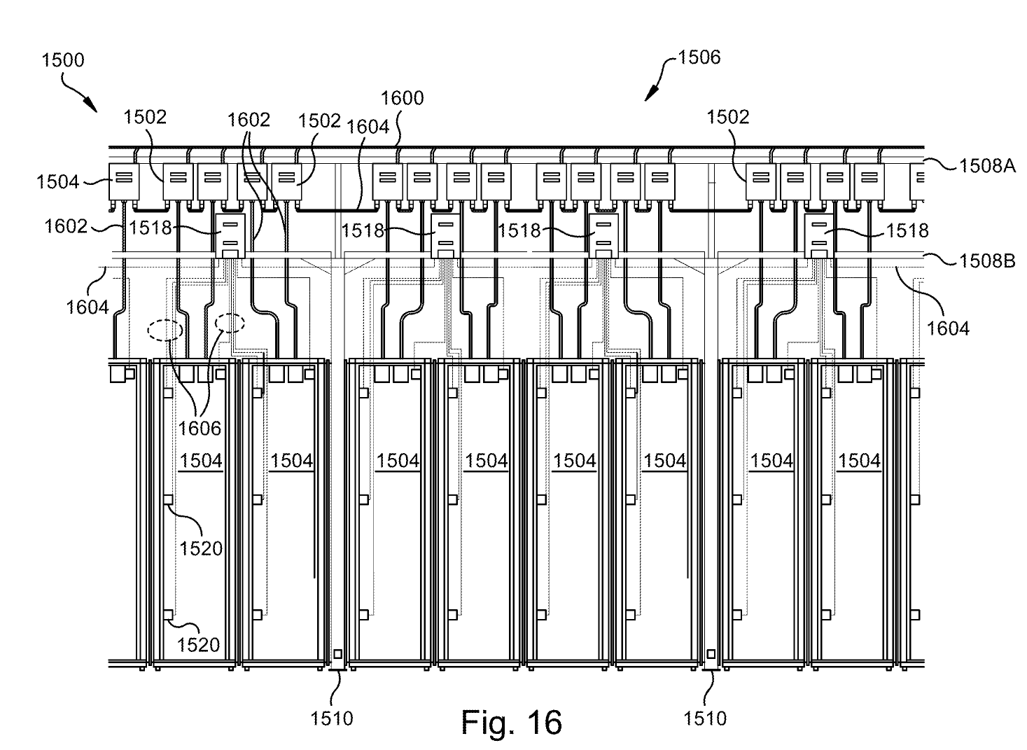

FIG. 16 is a cross-sectional view of a portion of one embodiment of the OIP 1500 of FIGS. 15A and 15B illustrating both the power modules 1502 and the I/O modules 1518 attached, in this instance, to the OIP 1500 and illustrating the coupling of each of these modules to the corresponding equipment rack 1504. In the embodiment of FIG. 16, the OIP 1500 includes two levels of horizontal support members 1508, which are designated upper horizontal support members 1508A and lower horizontal support members 1508B. The power modules 1502 are attached to the upper horizontal support member 1508A while the I/O modules 1518 are attached to the lower horizontal support member 1508B. In the sample embodiment of FIG. 16, each equipment rack 1504 includes two power distribution units (PDUs) (not shown) and a single power module 1502 is utilized to provide and monitor the electrical power supplied to each of these PDUs. Accordingly, two power modules 1502 are associated with each equipment rack 1504 in the embodiment of FIG. 16. This is in contrast to the embodiment of the power modules 1502 shown in FIG. 15A where a single module is used for both PDUs in a given equipment rack 1504, as will be described in more detail below with reference to FIG. 17.

Each power module 1502 receives alternating current (AC) power over an AC distribution line 1600 and supplies this AC power over a corresponding AC coupling line 1602 to a PDU in the corresponding equipment rack 1504. The AC coupling lines 1602 are labeled on the left side of FIG. 16 for several but not all of the power modules 1502 due to space limitations in the drawing. Each AC coupling line 1602 has a suitable receptacle at the end of the line for coupling to the corresponding PDU, as will be described in more detail below. Thus, the power modules 1502 in the embodiment of FIG. 16 include, in place of the power ports 1503 in the embodiment of FIG. 15A, the AC coupling lines 1602. As seen in the FIG. 16, there are two power modules 1502 associated with each equipment rack 1504, with each power module being coupled through a corresponding AC coupling line 1602 to the equipment rack. The power modules 1502 are interconnected through a module interconnection bus 1604 that includes low voltage power and communications links and which is connected to the controller module 1516 (FIGS. 15A and 15B), as will be described in more detail below.

The I/O modules 1518 are attached to the lower horizontal support member 1508B, each being positioned on the support member above the two equipment racks 1504 with which the module is associated. More specifically, as previously mentioned in this embodiment, each I/O module 1518 monitors the sensor signals from sensors 1520 contained in two equipment racks 1504. Each I/O module 1518 is coupled to the sensors 1520 in each associated equipment rack 1504 through corresponding sensor signal lines 1606. Once again, not all the sensor signal lines 1606 are labeled in FIG. 16 due to space limitations in the drawing. The sensor signal lines 1606 are labeled in the left-hand portion of FIG. 16. The I/O modules 1518 are similarly interconnected through the module interconnection bus 1604 and thereby to the controller module 1516 (FIGS. 15A and 15B), as will be described in more detail below.

In FIG. 16, the power modules 1502 and I/O modules 1518 are attached at different levels of the OIP 1500, namely to the upper horizontal support member 1508A and the lower horizontal support member 1508B, respectively. An actual embodiment of the OIP 1500 may indeed include such multiple levels of horizontal support members 1508, and indeed could include more than two such levels. FIG. 16 was, however, directed to such an embodiment for clarity of the figure since placing all the modules 1502 and 1518 next to each other on the same horizontal support member 1508 results in a drawing that is more difficult to understand. Embodiments of the OIP 1500 may, however, include only a single level of horizontal support members 1508.

The structure of the OIP 1500 provides a flexible and scalable solution for data centers 1506. This structure enables equipment cabinets or racks 1504 to be removed from and placed into the data center 1506 without the need to entirely reconfigure the OIP 1500. A new equipment rack 1504 need simply be assembled including the required sensors 1520 and suitable power receptacles for coupling to the AC coupling line 1602. The old equipment rack 1504 is then simply disconnected from the AC coupling lines 1602 and sensor signal lines 1606 and then physically removed from the data center 1506. A new equipment rack 1504 is then moved into place under the OIP 1500 and connected to the associated power modules 1502 and I/O module 1518 through the corresponding AC coupling lines 1602 and sensor signal lines 1606, respectively. The power consumed by and various operating parameters of this new equipment rack 1504 may then be monitored in the same way as for the old equipment rack, as will be described in more detail below. Suitable connectors may be utilized on the sensor signal line 1606 to allow for easy connection and disconnection of the sensors 1520 in an equipment rack 1504 from an I/O module 1518. Moreover, sensors 1520 may in this way be placed in equipment racks 1504 and throughout the data center 1506 as desired and the sensors may then be monitored via the module interconnection bus 1604 and controller module 1516 to control the overall operation of the data center, as will also be described in more detail below.

FIG. 17 is a functional block diagram of one of the power modules 1502 of FIG. 15A according to one embodiment of the present disclosure. In the embodiment of FIG. 17, the power module 1502 includes power meter circuitry 1700 coupled to the module interconnection bus 1604 to communicate with the controller module 1516 (FIGS. 15A and 15B). The power meter circuitry 1700 includes circuitry for sensing the AC power supplied through the power ports 1503 to the PDUs (not shown in FIGS. 15A and 15B) in the corresponding equipment rack 1504. In the embodiment of FIG. 17, this power sensing circuitry corresponds to current transformers CT that are electromagnetically coupled to the individual lines of the AC power line 1600. For example, where the AC power line 1600 is three-phase AC power, the current transformers CT would include a respective current transformer for each of the three AC phase lines, as will be appreciated by those skilled in the art. In this situation, the AC power line 1600 would include the three AC phase lines along with a neutral line, as will also be appreciated by those skilled in the art. In the embodiment of FIG. 17, the power module 1502 supplies power to two PDUs in a respective equipment rack 1504 through the respective power ports 1503 and also individually senses the AC power supplied to each of these PDUs. The power meter circuitry 1700 also receives power from the AC power line 1600 to operate the electronic circuitry contained in the power circuitry, which is represented in FIG. 17 through the arrow 1701.

The embodiment of the power module 1502 in FIG. 17 corresponds to the embodiment shown in FIG. 15A. Thus, each AC coupling line 1505 corresponds to a cord of a PDU that is coupled to one of the power ports 1503 of the power module 1502. The specific structure of the power ports 1503 may, of course, vary. In some embodiments the power ports 1503 are cord receptacles into which plugs on the AC coupling lines 1505 are inserted. These cord receptacles may be one or more of a NEMA 5-20P receptacle, NEMA L5-20P receptacle, L5-30P receptacle, NEMA L6-20P receptacle, NEMA L6-30P receptacle, NEMA L15-20P receptacle, NEMA L15-20P receptacle, NEMA L15-30P receptacle, NEMA L21-30P receptacle, Non-NEMA CS8365C receptacle, IEC 60309 3p4w receptacle, IEC 60309 4p5w receptacle. Any suitable type of receptacle 1503 may be used, and in other embodiments other suitable interconnection devices may be used in place of receptacles, such as screw terminals, for example.

In operation, the power meter circuitry 1700 senses the signals from the current transformers CT and processes these signals to determine the respective amounts of AC power consumed via the power ports 1503 by each of the PDUs in the corresponding equipment rack 1504. The power meter circuitry 1700 then communicates this power consumption data indicating power consumed by each of the PDUs over a communications bus 1702 portion of the module interconnection bus 1604. This data is communicated over the communications bus 1702 to the controller module 1516 (FIGS. 15A and 15B). The module interconnection bus 1604 includes the communications bus 1702 and a low voltage power bus 1704. Various suitable protocols and types of communications buses 1702 may be utilized, as will be appreciated by those skilled in the art. In one embodiment, the communications bus 1702 is a serial bus that implements the Modbus+ communications protocol to provide communications between each power module 1502 and the controller module 1516. Because the power meter circuitry 1700 receives power for operation from the AC power line 1600, power provided on the low voltage power bus 1704 is not needed. Thus, as seen in FIG. 17, the power module 1502 merely functions as a pass-through for the low voltage power bus 1704 such that low voltage power may be supplied to I/O modules 1518 downstream of the power module, where “downstream” means to I/O modules that are connected farther away from the controller module 1516 on the module interconnection bus 1604, as will be more easily understood and described in more detail below with reference to FIG. 20.

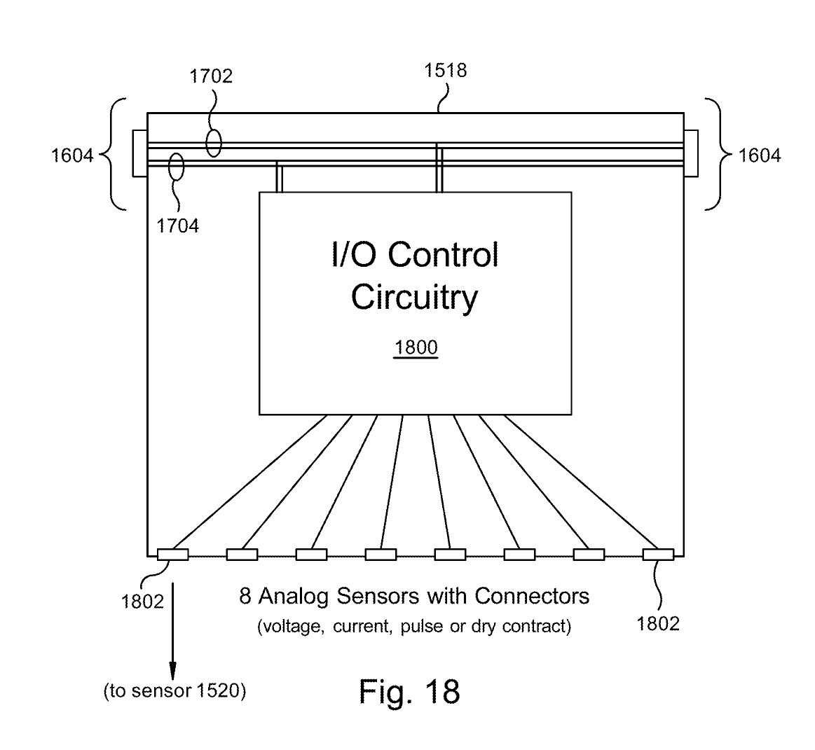

FIG. 18 is a functional block diagram of one of the I/O modules 1518 of FIGS. 15B and 16 according to one embodiment of the present disclosure. The I/O module 1518 includes I/O control circuitry 1800 coupled to the module interconnection bus 1604. The control circuitry 1800 is coupled to the low voltage power bus 1704 of the interconnection bus 1604 to receive power for operating the circuitry. The control circuitry 1800 is also coupled to a number of sensor connectors 1802, each of which is adapted to receive a sensor signal line 1606 (FIG. 16) to thereby couple a respective sensor 1520 to the I/O module 1518. The sensors 1520 may be any type of sensor to implement the desired control of the data center 1506 containing the equipment rack 1504 including the sensor. The sensors 1520 may be temperature, humidity, door contact, and so on, being any suitable type of sensor. Moreover, each of these sensors 1520 may be any suitable type of sensor, both analog and digital sensors. In the embodiment of FIG. 18, each of the sensors 1520 coupled via the connectors 1802 to the control circuitry 1800 is assumed to be an analog sensor such that the sensors 1520 are analog sensors. Digital sensors 1520 could also be connected to the control circuitry 1800 in other embodiments.

In operation, the I/O control circuitry 1800 senses the signals from the sensors 1520 coupled to the I/O module 1518 and processes these signals to thereby sense the desired operating parameters, such as temperature and humidity, of the corresponding equipment rack 1504. The I/O control circuitry 1800 communicates operating parameter data indicating these sensed operating parameters over the communications bus 1702 of the module interconnection bus 1603 to the controller module 1516 (FIGS. 15A and 15B). The sensors 1520 may be any suitable type of sensor to sense the desired operating parameter, including voltage, current, pulse, ultrasonic, and dry contact type sensors, as will be appreciated by those skilled in the art.

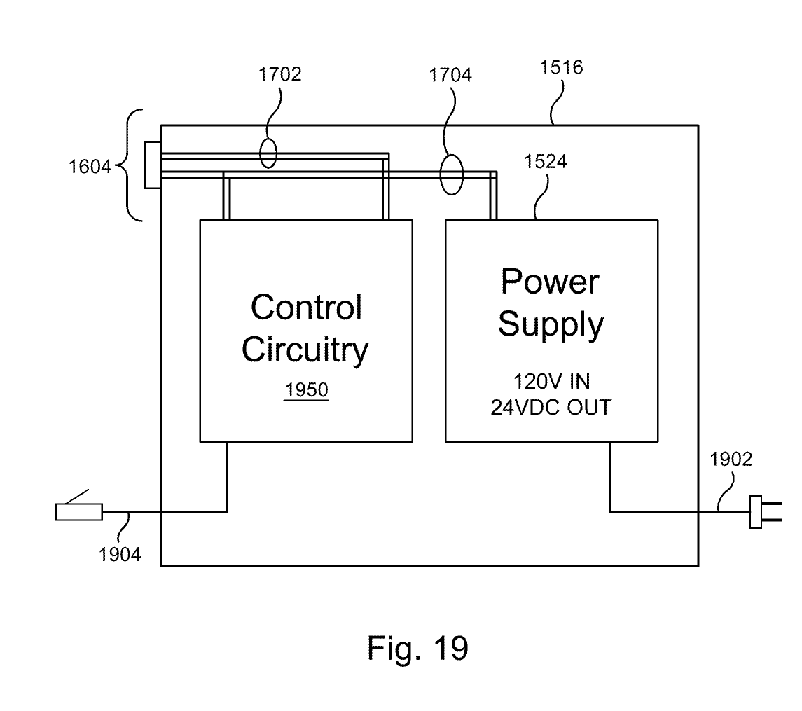

FIG. 19 is a functional block diagram of the controller module 1516 of FIGS. 15A and 15B according to one embodiment of the present disclosure. The controller module 1516 includes control circuitry 1900 that controls the operation of the controller module 1516 and functions as the master of the communications bus 1702 portion of the module interconnection bus 1604. In the embodiment of FIG. 19 the controller module 1516 also includes a DC power supply 1524 (FIG. 15B) that generates a DC voltage from an AC power source 1902 and supplies this DC voltage over the low voltage power bus 1704 portion of the module interconnection bus 1604 to all the I/O modules 1518 (See FIG. 18) connected to the interconnection bus. The voltage supplied on the bus 1704 may, for example, be 24 VDC.

In operation, the control circuitry 1900 controls the overall operation of all the power modules 1502 (See FIG. 17) and I/O modules 1518 (See FIG. 18) coupled to the module interconnection bus 1604. The control circuitry 1900 receives the determined power consumption data from the power modules 1502 and the determined operating parameter data from the I/O modules 1518. The control circuitry 1900 is also coupled to a control network through a suitable network port 1904, such as an Ethernet port, and in this way communicates operating information over a higher-level network to a higher-level control system (not shown) that controls the overall operation of the data center 1506 including the controller module 1516. For example, in response to temperature sensors or humidity sensors sending undesirable temperature or humidity levels in a given equipment rack 1504, the higher-level control system may adjust the operation of fans in the equipment rack or the air conditioning units 202 (FIG. 2A) in the data center to control the overall operation of the data center and maintain desired operating parameters in the individual equipment racks 1504 and for the entire data center 1506.

The network port 1904 enables a single controller module 1516 that controls a number of power modules 1502 and I/O modules 1518 to be coupled to the higher-level network (e.g., an Ethernet network). In this way, only a single address, such as an IP address, is required for the single controller module 1516 to thereby enable the higher-level network control monitor and control a large number of equipment racks 1504. The number of equipment racks 1504 that may be controlled by a given controller module 1516 depends on the type of communications bus 1702 that is utilized, as will be appreciated by those skilled in the art. Although the communications bus 1702 is shown as including two lines in the above-described embodiments, in other embodiments this bus may include more than two transmission lines. The same is true for the low voltage power bus 1704, which may also include more than two lines such as, for example, to provide more than one voltage level to the I/O modules 1518.

FIG. 20 is a functional block diagram illustrating a module network 2000 formed by the interconnection of the controller module 1516, power modules 1502 and I/O modules 1518 through the module interconnection bus 1604. A simple four conductor (two conductors for the low voltage power bus 1704 and two for the communications bus 1702 as shown in FIG. 19) cable having suitable connectors to couple each section of cable to one of the modules 1516, 1518 or 1512 may be used to interconnect all the modules and collectively form the module interconnection bus 1604. The final module 1502 or 1518 coupled to the bus 1604 may include a termination resistor 2002 coupled to the connector that is not connected to another module in order to prevent unwanted reflections and provide desired matching that improves the operation of the interconnection bus 1604, as will be appreciated by those skilled in the art.

Through the low voltage power bus 1704 (FIG. 17) of the interconnection bus 1604, the power supply 1524 in the controller module 1516 supplied the required power to all the I/O modules 1518 coupled to the interconnection bus. Also note that each of the power modules 1502 functions to simply pass through the low voltage power on the low voltage power bus 1704 so that subsequent or “downstream” I/O modules 1518 receive the required voltage for operation. For example, one I/O module 1518 in the lower right portion of FIG. 20 is “downstream” of the power module 1502 in the upper left of the figure. The pass through function of the power module 1502 in the upper left of FIG. 20 for the low voltage power on the low voltage power bus 1704 of the module interconnection bus 1604 allows these two downstream I/O modules 1518 to receive the required voltage. This provides flexibility and simplicity when adding and removing modules of any type to or from the network 2000.

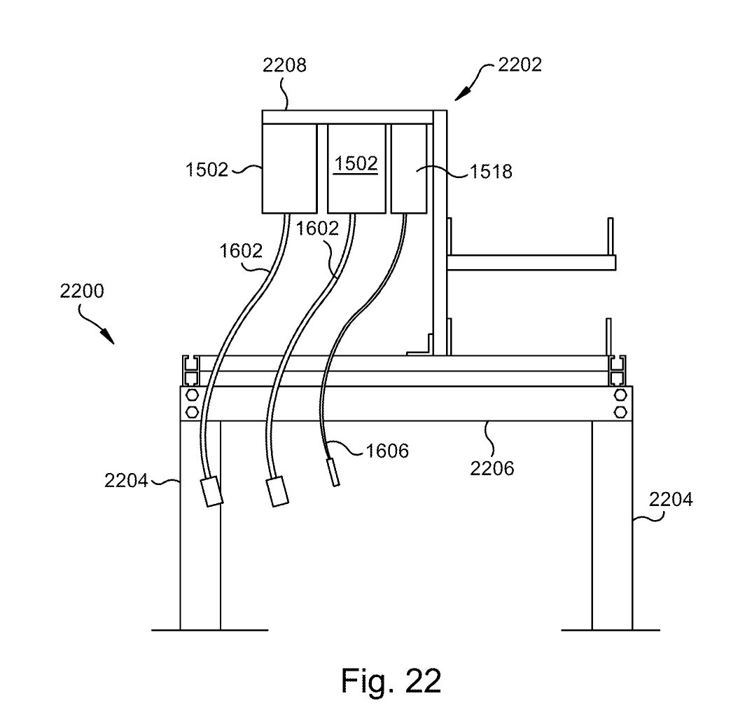

FIG. 21 is a cross-sectional view of a portion of an OIP 2100 including multiple levels of horizontal support members 2102A, 2012B positioned over equipment racks 1504 according to another embodiment of the present disclosure. The OIP 2100 includes lower vertical support members 2104 along with upper vertical support members 2106 attached on top of horizontal support member 2102A and which support upper horizontal support member 2102B. Cable routing structures 2108 and 2110 are also attached to the upper vertical support members 2106. The OIP 2100 is illustrated merely to demonstrate that many configurations of the OIP according to embodiments of the present disclosure are possible. In the embodiment of FIG. 21, the I/O modules 1518 are attached to the upper horizontal support member 2102B while pairs of power modules 1502 are attached to the lower horizontal support member 2102A, each pair of power modules being for a corresponding equipment rack 1504. Thus, in this embodiment the I/O modules 1518 are attached above the power modules 1502, which is the converse of the embodiment of the OIP illustrated in previously described with reference to FIG. 16. The sense signal lines interconnecting each I/O module 1518 and the corresponding equipment racks 1504 and the AC coupling lines interconnecting each power module 1502 and the corresponding equipment rack are not shown in FIG. 21 merely to simplify the figure. FIG. 22 is a cross-sectional view of a portion of an OIP 2200 including an L-shaped mounting bracket 2202 for mounting the power modules 1502 and an associated I/O module 1518 for a corresponding equipment rack 1504 (not shown) according to a further embodiment of the present disclosure. In this embodiment, the OIP 2200 includes vertical support members 2204 and a horizontal support member 2206 on which the L-shaped mounting bracket 2202 is mounted. Two power modules 1502 and an I/O module 1518 for a respective equipment rack 1504 are attached to a horizontal portion 2208 of the L-shaped mounting bracket 2202. In this way, the mounting bracket 2202 can be attached to the horizontal support member 2206 where needed to position the power modules 1502 and I/O module 1518 proximate the equipment rack 1504 to which these modules are connected. The AC coupling lines 1602 for the power modules 1502 and the sensor signal lines 1606 for the I/O module 1518 are shown in FIG. 22 dangling from the respective modules and not connected to the corresponding equipment rack 1504.

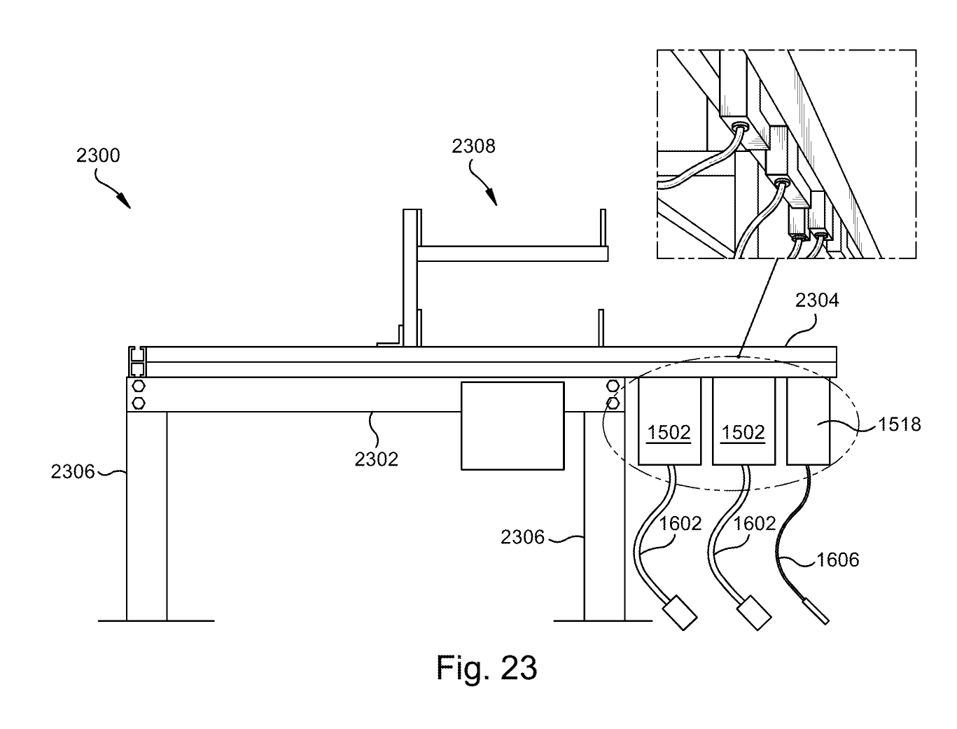

FIG. 23 is a cross-sectional view of a portion of an OIP 2300 where a horizontal support member 2302 includes an end portion 2304 that extends beyond an end vertical support member 2306, and where a pair of power modules 1502 and an I/O module 1518 associated with a respective equipment rack 1504 (not shown) are mounted to this end portion according to still another embodiment of the present disclosure. Once again, this embodiment merely illustrates the flexibility of arranging the various modules on the OIP 2300. The OIP 2300 also includes a ladder basket 2308 is shown attached on top of the horizontal support member 2302.

The OIP 1500, 2100, 2200, 2300 including the power modules 1502, I/O modules 1518, and controller module 1516 provides a flexible and efficient approach for monitoring, controlling, and replacing equipment racks 1504 in a data center 1506. The I/O modules 1518 mean that no “intelligent,” i.e. complicated and expensive, PDUs need be utilized in the equipment racks 1504. This reduces the cost of the required PDUs and simplifies replacement of an equipment rack 1504 since no new intelligent PDU contained in a new equipment rack must be coupled to the control network (i.e., to the module interconnection bus 1604). Similarly, simple, low cost sensors 1520 may be utilized in the equipment racks 1504, likewise avoiding complicated and expensive “intelligent” sensors, since the circuitry for processing signals from the sensors is contained not within the equipment rack but within the I/O modules 1518. This allows for a higher sensor density, namely a larger number of lower cost sensors 1520, to be utilized in the equipment racks 1504 and in the data center 1506. Moreover, the I/O modules 1518 allow sensors 1522 (FIG. 15B) outside the equipment racks 1504 to also be utilized, such as sensors to measure temperature and humidity in the data center 1506 itself and not within a particular equipment rack. Moreover, such sensors 1522 outside the equipment racks 1504 may be security-type sensors, such as motion sensors to allow the detection of unauthorized or unexpected personnel in the data center 1506, or door-contact sensors to indicate the unwanted or unauthorized opening or open-state of doors of the equipment racks 1504.

In another embodiment, the power modules, I/O modules, and controller modules are attached not to an overhead infrastructure platform but to the overhead electrical grounding mesh and mechanical grid structure 102 of FIG. 1. In this embodiment, the power modules and I/O modules are positioned on the grid structure 102 so that they are proximate the equipment rack 108 to which they are connected. In any of these embodiments, the power modules, I/O modules, and controller modules may, in place of or in addition to the equipment racks 108, 1504, be coupled to other types of electronic devices or equipment.

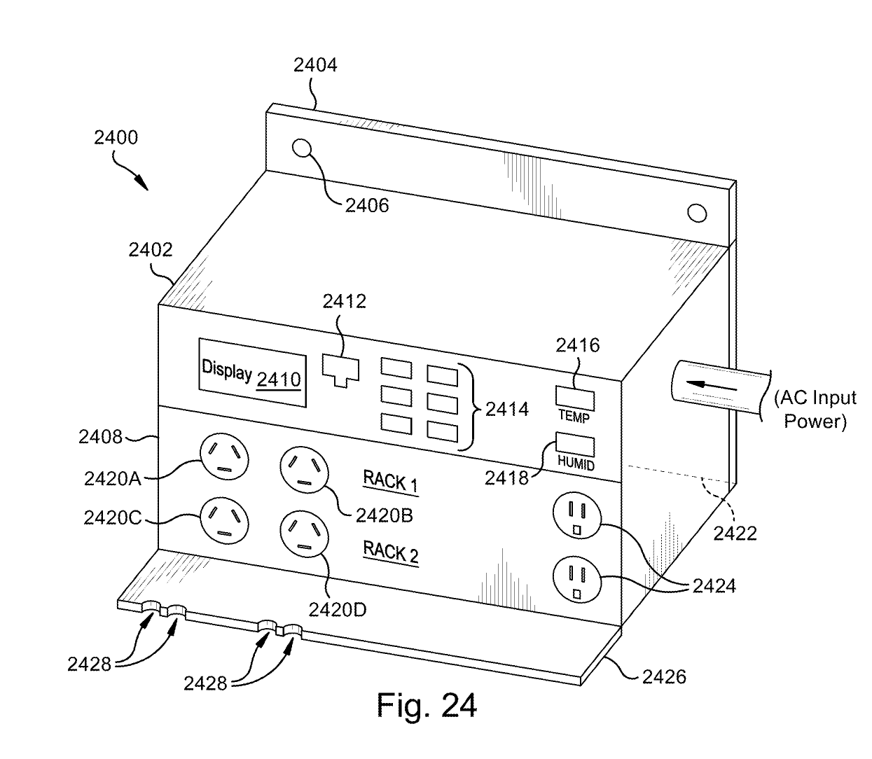

FIG. 24 is a perspective view of an external networked power distribution unit (PDU) 2400 that may be mounted to the mechanical grid structure 102, 602 of FIGS. 1, 6, respectively, or to the overhead infrastructure platform (OIP) 1500, 2100, 2200, 2300 of FIGS. 15A, 21, 22 and 23, respectively, according to another embodiment of the present disclosure. The external networked PDU 2400 is standalone unit that is similar to a combination of the power module 1502 of FIGS. 15A and 17 and the I/O modules 1518 of FIGS. 15B and 18. The external networked PDU 2400 is mounted in a fixed location to the grid structure 102 of FIG. 1, the OIP 1500, 2100, 2200, 2300 or any other convenient “fixed” location within the data center. The external networked PDU 2400 receives AC input power and is then coupled to associated equipment racks 108/1504 (FIGS. 1 and 15) and remote sensors, and to a suitable network, such as an Ethernet network, to allow for remote monitoring and control of the associated equipment racks, as will be described in more detail below.

The external networked PDU 2400 includes a housing 2402 having a back panel 2404 including one or more mounting holes 2406 for attaching the external networked PDU to the grid structure 102, 602 or the OIP 1500, 2100, 2200, 2300. A front panel 2408 includes a display 2410 which may display pertinent parameters being sensed by the external networked PDU 2400. A network port 2412, such as an Ethernet port, along with a number of sensor ports 2414, are contained on the front panel 2408 for connecting the external networked PDU 2400 to a network and remote sensors contained in associated equipment racks 108/1504, respectively. In addition, a temperature sensor port 2416 and humidity sensor port 2418 may be provided on the front panel 2408 for coupling to a temperature sensor and humidity sensor, respectively, positioned in the data center 100 or 1506.

The lower portion of the front panel 2408 includes a number of power receptacles or ports 2420A-D. In the sample embodiment of FIG. 24, the first two power ports 2420A and 2420B are to be coupled to a first equipment rack 108/1504 while the second two power ports 2420C and 2420D are to be coupled to a second equipment rack. In other embodiments additional power ports 2420 may be provided for coupling to additional equipment racks 108/1504, or a group of power ports may be provided for coupling to a single equipment rack. The power ports 2420 may be any suitable type of plug receptacle or other type of connection to which power strips in the equipment racks 108/1504 may be plugged into. Alternatively, the power ports 2420 could alternatively be AC coupling lines analogous to the AC coupling lines 1602 discussed with reference to the embodiment of FIG. 16. In such an embodiment, cords having suitable power receptacles on the ends of the cords would extend out of the front panel 2408, or from the bottom of the external networked PDU 2400, and then down into the associated equipment racks 108/1504. In another embodiment, the lower portion of the front panel 2408 could be downward angled as indicated by the dotted line 2422.

The lower portion of the front panel 2408 also includes one or more convenience power receptacles 2424 for allowing test equipment (not shown) to be plugged into the external networked PDU 2400. This eliminates the need for test personnel to plug such test equipment into a power receptacle contained in one of the associated first and second equipment racks 108/1504. A lower edge panel 2426 includes grooves 2428 into which power cables plugged into to the power ports 2420A-D may be placed for strain relief purposes.

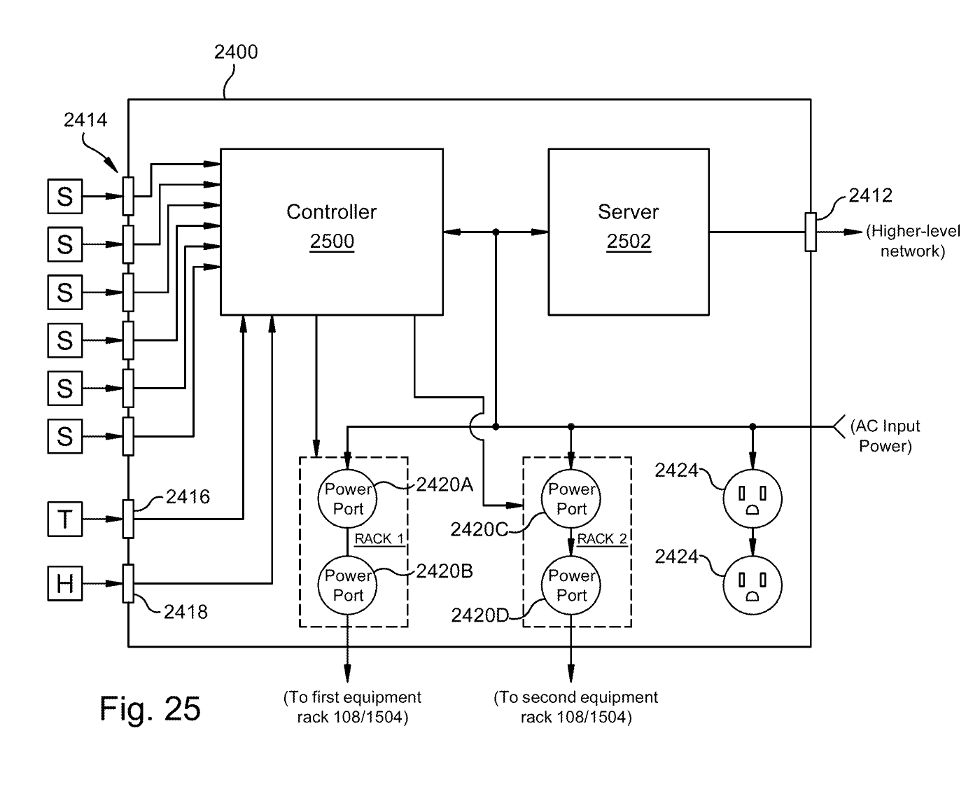

FIG. 25 is a functional block diagram illustrating one embodiment of the external networked PDU 2400 of FIG. 24. In this embodiment, the external networked PDU 2400 includes a controller 2500 that controls the overall operation of the PDU. The controller 2500 is coupled through the sensor ports 2414 to various types of remote sensors S contained in each of the equipment racks 108/1504 coupled to the external networked PDU. These sensors S may be coupled to the controller 2500 through any suitable type of communication line, such as analog signal lines or digital communication links such as RS-232, RS-485, and so on. The sensors S may be any suitable type of sensor. In one embodiment, the sensors S include a water detection sensor or sensors for sensing the presence of water in the equipment racks and contact switch sensors for sensing whether each of the doors of the equipment racks 108/1504 are opened or closed. One of the sensors S could also be a camera and in this way function as a security sensor. The controller 2500 is also coupled through the temperature sensor port 2416 to a temperature sensor T and through the humidity sensor port 2418 to a humidity sensor H. These temperature and humidity sensors T, H are positioned in the data center 100/1506 to sense temperature and humidity in the data center itself and not within a particular equipment rack 108/1504.

The controller 2500 may also sense whether a plug is disconnected from one of the power ports 2420A-D. This disconnection sensing would not typically be provided for the convenience power receptacles 2424. The controller 2500 also includes circuitry for sensing the AC power supplied from the AC input power through the power ports 2420A and 2420B to the first equipment rack 108/1504 and the AC power supplied through the power ports 2420C and 2420D to the second equipment rack. As previously discussed with reference to FIG. 17, such power sensing circuitry may correspond to current transformers CT that are electromagnetically coupled to the individual lines of the AC input power lines, as well as other suitable circuitry as will be appreciated by those skilled in the art.

The controller 2500 senses signals from the sensors S, T, H and the sensors (e.g., current transformers CT) that sense AC power supplied through the power ports, and processes all these signals to thereby sense the associated parameters. The controller 2500 then supplies sensed data corresponding to these sensed parameter to a server 2502 which, in turn, communicates this sensed data through the network port 2412 and over a higher-level network to a higher-level control system (not shown) to control the overall operation of the data center 100/1506. In one embodiment, the server 2502 is a Web server the allows a user to remotely access and control the external networked PDU 2400 over the higher-level network through a Web-based interface provided by the server. In this way, the server 2502 provides a Web interface over the higher-level network to enable a remote user to adjust and customize operating parameters of the external networked PDU 2400 and to display sensed data from the external networked PDU. In one embodiment, the Web interface provided by the server 2502 enables a user to name each external networked PDU 2400 and to specify the location of the PDU.

The server 2502 also has an IP address for use during configuration of the external networked PDU 2400 by a remote user. And note that because the PDU 2400 itself is fixed a particular location in the data center 100/1506, old equipment racks 108/1504 can be removed and new ones installed and coupled to the PDU. The server 2502 will retain the same IP address on the higher-level network and will accordingly now sense and communicate data for the new equipment racks 108/1504. There is no need to track where a given IP address is physically located when new equipment racks 108/1504 are installed with the external networked PDU 2400. This is true because the PDU 2400 is mounted in a fixed physical location in a given data center 100/1506 and assigned an IP address on the higher-level network, and this does not change when new equipment racks 108/1504 are coupled to the PDU. The PDU 2400 may need to be reconfigured in this situation to account for new quantities or types of sensors S contained in the new equipment racks 108/1504 and coupled to the PDU, but physical location of the PDU and the IP address of the PDU do not change, eliminating the need to track physical locations of IP addresses on the higher-level network.

The server 2502 may support security protocols like SSL and HTTPS and may also allow DHCP static IP settings as well as default gateway and DNS settings. The server 2502 may also allow for a simple network time protocol (SNTP) server to be configured for maintaining the correct time for time stamps of historical data and system logs that may be generated by the PDU 2400. Configuration settings for the PDU 2400 may be saved to a non-volatile memory so the PDU can update its clock after a power cycle and may also utilize a public time server. When no SNTP server is configured, the PDU 2400 may utilize alternate methods of generating time stamps where the time is marked relative to elapsed time, for example.

The server 2502 may also include a real time clock with a short power back-up provided by a suitable capacitor or a battery. The interface of the server 2502 may allow for the setup of emails to be sent by the PDU 2400 based on configured conditions. The server 2502 may also allow for a ping to be sent from the PDU 2400 to a destination via the higher-level network for troubleshooting purposes.

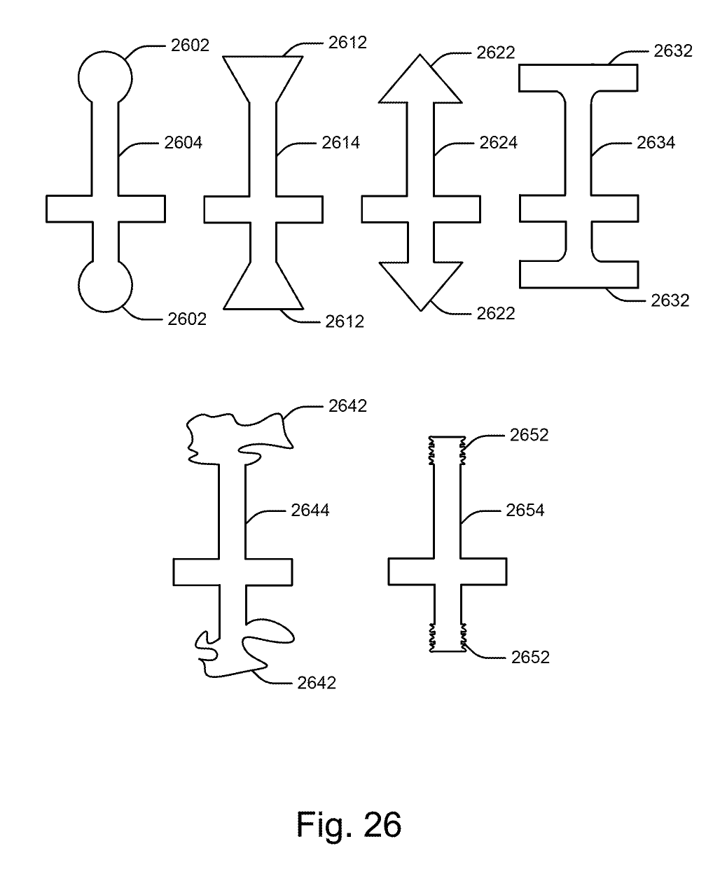

FIG. 26 illustrates various cross-sectional shapes of a bead at upper and lower portions of a grid-beam (e.g., a transverse grid-beam, a longitudinal grid-beam, etc.), according to various embodiments of the present disclosure. FIG. 26 includes a rounded bead 2602 (e.g., upper and lower rounded bead 2602) associated with a grid-beam section 2604, a triangular bead 2612 (e.g., upper and lower triangular bead 2612) associated with a grid-beam section 2614, another triangular bead 2622 (e.g., another upper and lower triangular bead 2622) associated with a grid-beam section 2624, an I-beam flanged bead 2632 (e.g., upper and lower I-beam flanged bead 2632) associated with a grid-beam section 2634, a generic shaped bead 2642 (e.g., upper and lower generic shaped bead 2642) associated with a grid-beam section 2644, and a textured bead 2652 (e.g., upper and lower textured bead 2652) associated with a grid-beam section 2654. The bead 622 shown in FIG. 6, the bead 700 shown in FIG. 7, the bead 1104 shown in FIG. 10 and/or a bead shown in another figure of the present disclosure can be shaped, for example, as the rounded bead 2606, the triangular bead 2612, the other triangular bead 2622, the I-beam flanged bead 2632, the generic shaped bead 2642, or the textured bead 2652. However, it is to be appreciated that the bead 622 shown in FIG. 6, the bead 700 shown in FIG. 7, the bead 1104 shown in FIG. 10 and/or a bead shown in another figure of the present disclosure can be associated with a different cross-sectional shape. It is also to be appreciated that the rounded bead 2606, the triangular bead 2612, the other triangular bead 2622, the I-beam flanged bead 2632 and the generic shaped bead 2642 can comprise a smooth surface or a textured surface.

Even though various embodiments and advantages of the present disclosure have been set forth in the foregoing description, the present disclosure is illustrative only, and changes may be made in detail and yet remain within the broad principles of the present disclosure. Many of the specific details of certain embodiments are set forth in the description and accompanying figures to provide a thorough understanding of such embodiments. One skilled in the art will understand, however, that the subject matter of the present disclosure may be practiced without several of the details described. Moreover, one skilled in the art will understand that the figures related to the various embodiments are not to be interpreted as necessarily conveying any specific or relative physical dimensions. Specific or relative physical dimensions, if stated, should not to be considered limiting unless the claims expressly state otherwise. Further, illustrations of the various embodiments when presented by way of illustrative examples are intended only to further illustrate certain details of the various embodiments, and should not be interpreted as limiting the scope of the appended claims.

What is claimed is:

1. An overhead electrical grounding mesh and mechanical grid structure for a data center, the grid structure comprising a plurality of grid beams, each of the grid beams being a rigid and electrically conductive grid beam to provide an overhead structure configured to be positioned over electronic equipment in the data center, the grid structure being configured to provide support for electronic equipment connected to the grid structure and to provide support for mechanical equipment in the data center that is connected to the grid structure, and the grid structure further adapted to be electrically coupled to the electronic equipment to provide an electrically conductive ground mesh for the electronic equipment in the data center.

2. The overhead electrical grounding mesh and mechanical grid structure of claim 1, wherein the mechanical equipment includes a ladder.

3. The overhead electrical grounding mesh and mechanical grid structure of claim 2, wherein the mechanical equipment further includes a catwalk.

4. The overhead electrical grounding mesh and mechanical grid structure of claim 1,
wherein the intersection of each of the plurality of grid beams forms a cross-beam portion, and
wherein at least some of the cross-beam portions are operable to allow grid beams to be repositioned to provide access to a space above the grid structure.

5. The overhead electrical grounding mesh and mechanical grid structure of claim 4, wherein each cross-beam portion comprises an attachment and hinge structure operable to operable to raise and lower corresponding grid beams to provide access to the space above the grid structure.

6. The overhead electrical grounding mesh and mechanical grid structure of claim 4, wherein each cross-beam portion comprises a spring that is operable when secured in position to hold the corresponding cross beams in place and is removable to enable at least one of the cross beams to be removed to provide access to the space above the grid structure.

7. The overhead electrical grounding mesh and mechanical grid structure of claim 4, wherein the spring is positioned on a bottom of the cross-beam portion.

8. The overhead electrical grounding mesh and mechanical grid structure of claim 1, wherein the grid structure is further configured to support ceiling tiles.

9. An overhead infrastructure platform comprising at least one horizontal support member configured to be positioned over equipment racks contained in a data center, the overhead infrastructure platform including a module network formed by the interconnection, through a module interconnection bus, of a controller module, at least one power module and at least one I/O module, each power module and each input/output module being physically attached to the horizontal support member proximate an equipment rack to which the module is electrically coupled.

10. The overhead infrastructure platform of claim 9, wherein the module interconnection bus comprises a low voltage power bus and a communications bus.

11. The overhead infrastructure platform of claim 9, wherein the communications bus comprises a Modbus+ communications bus.

12. The overhead infrastructure platform of claim 10, wherein each of the input/output modules comprises:
a plurality of sensor connectors, each sensor connector is configured to be coupled a corresponding sensor to receive corresponding sensor signals; and
input/output control circuitry coupled to the low voltage power bus, communications bus, and to each of the sensor connectors, the input/output control circuitry operable to receive sensor signals from sensors coupled to the sensor connectors and operable to processes these signals to thereby sense operating parameters, and further operable to communicate operating parameter data indicating these sensed operating parameters over the communications bus.

13. The overhead infrastructure platform of claim 12, wherein the types of sensors coupled to the sensor connectors include sensors for sensing temperature, current, air quality, air flow, humidity, leak, pressure and power.

14. The overhead infrastructure platform of claim 13, wherein some of the sensors are physically located within one of the equipment racks associated with the input/output module and some of the sensors are located external to any equipment rack.

15. The overhead infrastructure platform of claim 10, wherein each of the power modules comprises:
at least one power port including an input configured to be coupled to receive AC power and an output configured to be coupled to an equipment rack; and
power meter circuitry coupled to the communications bus and including power sensors coupled to each power port, the power meter circuitry operable to through the power sensors to sense AC power supplied through each power port and to communicate power consumption data indicating the supplied AC power for each power port over the communications bus.

16. The overhead infrastructure platform of claim 15, wherein the power meter circuitry is further coupled to receive the AC power for powering electronic circuitry forming the power meter circuitry.

17. The overhead infrastructure platform of claim 15, wherein the power sensors comprise current transformers.

18. The overhead infrastructure platform of claim 15, wherein each of the power ports comprises a cord receptacle.

19. The overhead infrastructure platform of claim 18, wherein each cord receptacle comprises one of NEMA 5-20P receptacle, NEMA L5-20P receptacle, L5-30P receptacle, NEMA L6-20P receptacle, NEMA L6-30P receptacle, NEMA L15-20P receptacle, NEMA L15-20P receptacle, NEMA L15-30P receptacle, NEMA L21-30P receptacle, Non-NEMA CS8365C receptacle, IEC 60309 3p4w receptacle, IEC 60309 4p5w receptacle.

20. The overhead infrastructure platform of claim 10, wherein the controller module comprises control circuitry coupled to the communications bus and to the low voltage power bus, the control circuitry operable to communicate over the communications bus to receive operating information from each power module and each input/output module coupled to the communications bus, and the control circuitry further comprising a network port through which the control circuitry is further operable to communicate this operating information through the network port to a higher-level network.

21. The overhead infrastructure platform of claim 20, wherein the network port comprises and Ethernet port.

22. The overhead infrastructure platform of claim 20, wherein the controller module further comprises a power supply coupled to the low voltage power bus and operable to supply low voltage on the low voltage power bus.

23. The overhead infrastructure platform of claim 9, wherein the overhead infrastructure platform includes multiple levels of horizontal support members with power modules and input/output modules being attached to each of these multiple levels.

24. The overhead infrastructure platform of claim 9, wherein at least one module of the module network is attached to a bead of the horizontal support member.

25. An external networked power distribution unit configured to be physically attached to an overhead structure in a data center and to be electrically coupled to at least one equipment rack in the data center, the external networked power distribution unit including server circuitry operable to communicate sensed information from the power distribution unit over a higher-level network, the server circuitry having a fixed address on the higher-level network that is associated with the physical location of the external networked power distribution unit.

26. The external networked power distribution unit of claim 25 further comprising controller circuitry for sensing signals from remote sensors contained in each equipment rack and in the data center and for sensing the electrical power consumed by each equipment rack.

27. The external networked power distribution unit of claim 25, wherein the overhead structure comprises an overhead electrical grounding mesh and mechanical grid structure.

28. The external networked power distribution unit of claim 25, wherein the overhead structure comprises an overhead infrastructure platform.
